(19) United States
(12) Patent Application Publication
(10) Pub. No.: US 2002/0097173 A1
(43) Pub. Date: Jul. 25, 2002

(54) Code converter for coding and decoding digital data

(75) Inventor: Satoshi Itoi, Tokyo (JP)

Correspondence Address: FOLEY AND LARDNER, SUITE 500, 3000 K STREET NW, WASHINGTON, DC, 20007, US

(73) Assignee: NEC CORPORATION

(21) Appl. No.: 09/984,478

(22) Filed: Oct. 30, 2001

(30) Foreign Application Priority Data
Oct. 31, 2000 (JP) 2000-332300

(51) Int. Cl. H03M 5/00; H03M 7/00

(52) U.S. Cl. 341/58; 341/106

(57) ABSTRACT

A code converter of the present invention converts m data bits to n channel bits (m<n) and records the n channel bits in a recording medium. The code converter includes a basic table made up of a plurality of tables smaller in number than 2^{m} defined on the basis of a bit pattern required of the codes. A converting circuit codes all data of the m data bits to the n channel bits by calculation using the basic table. The code converter is operable with a minimum number of tables and therefore with a minimum of circuit scale.

### BACKGROUND OF THE INVENTION

1. Field of the Invention

The present invention relates to a code converter for coding digital data to be recorded in an optical disk (including a magnet-optical disk and a phase change disk), magnetic disk, magnetic tape or similar recording medium in the form of codes and decoding the codes. More particularly, the present invention relates to a code converter capable of reducing the number of conversion tables necessary for coding and decoding.

2. Description of the Background Art

Generally, when digital codes are transferred via a communication channel or recorded in the form of a data sequence, it is necessary to modulate and demodulate the codes to a signal feasible for a transfer path or channel. Particularly, for high packing density, it is a common practice to code the bit sequence of input data or data bits to a sequence of channel bits by using a conversion table and then modulate the sequence of channel bits to a channel signal by an NRZI (Non-Return to Zero Inverse) rule.

An NRZI signal produced by NRZI modulation has a waveform whose inversion interval must lie in a preselected range in relation to the frequency characteristic of a channel or tracking control over the head of a recording/reproducing apparatus. The inversion interval refers to a duration over which the high level (H) or the low level (L) of the waveform continues. In addition, a DC component, i.e., a difference in duration between high levels or low levels must be small. It follows that channel bits derived from input data bits must have an inversion interval always lying in a preselected range. Specifically, the number of continuous “0” bits sandwiched between “1” bits must be d or more (generally referred to as “d limitation”), but k or less (generally referred to as “k limitation”). These limitations are collectively referred to as a (d, k) limitation. Further, in order to reduce the low frequency component of the final signal, i.e., NRZI signal, a channel bit sequence that reduces the absolute value of a DSV (Digital Sum Variation) is selected.

More specifically, codes to be recorded achieve a more desirable characteristic with a decrease in minimum inversion interval (Tmin), an increase in maximum inversion interval (Tmax), and an increase in a sensing window width (Twin). In addition, the DC component of the codes should preferably be free. (1, 7) coding is a typical coding scheme proposed to satisfy such conditions. (1,7) coding converts two-bit bit data to three-bit channel bits or converts four-bit bit data to six-bit channel bits and then records the channel bits by using the NRZI rule. (1, 7) coding can provide the channel bits with the minimum inversion interval of 1.33 Tb (Tb: data bit interval), the maximum inversion interval of 5.33 Tb, and a sensing window width of 0.67 Tb. This kind of scheme, however, cannot make the DC component free.

Japanese Patent Laid-Open Publication No. 2000-183750, for example, discloses a code converter constructed to convert sixteen-bit data to twenty-five channel bits while making the DC component free. The code converter disclosed uses three different kinds of conversion tables A, B and C each adding a particular bit pattern to all possible patterns (2¹⁶=65536 patterns) of sixteen data bits. By selecting optimal one of the 65536 conversion tables, the code converter provides the twenty-five channel bits with the minimum number of continuous bits of two and the maximum number of continuous bits of eight, thereby making most of the advantage of the (1, 7) coding scheme. In addition, the code converter reduces the DC component by reducing the disadvantage of the (1, 7) coding scheme.

The problem with conventional code converters in general is that when the number of data bits to be coded is great, there must be used a conversion table with an impracticably huge circuit scale. More specifically, when m data bits should be converted to n channel bits (m<n), a conversion table with as great as 2^{m} outputs is required. For example, to convert sixteen data bits, a conversion table capable of dealing with at least 65536 (2¹⁶) different input patterns is necessary. This problem is more serious with the code converter taught in the above document 2000-183750 using three different kinds of conversion tables.

Technologies relating to the present invention are also disclosed in, e.g., Japanese Patent Laid-Open Publication Nos. 8-287620, 9-162744 and 11-176108 as well as in WO 96/19044.

### SUMMARY OF THE INVENTION

It is an object of the present invention to provide a code converter capable of reducing the scale of a conversion table necessary for conversion between input data bits and channel bits to be recorded.

A code converter of the present invention converts m data bits to n channel bits (m<n) and records the n channel bits in a recording medium. The code converter includes a basic table made up of a plurality of tables smaller in number than 2^{m} defined on the basis of a bit pattern required of the codes. A converting circuit codes all data of the m data bits to the n channel bits by calculation using the basic table.

### BRIEF DESCRIPTION OF THE DRAWING

The above and other objects, features and advantages of the present invention will become more apparent from the following detailed description taken with the accompanying drawings in which:

FIG. 1 shows a specific format of a conventional conversion table for a code converter;

FIG. 2 is a schematic block diagram showing coding circuitry included in a code converter embodying the present invention;

FIG. 3 is a schematic block diagram showing decoding circuitry also included in the illustrative embodiment;

FIG. 4 shows part of a specific conversion table for converting sixteen data bits to twenty-four channel bits;

FIG. 5 shows the other part of the conversion table;

FIGS. 6 through 21 show consecutive tables constituting a basic table unique to the illustrative embodiment;

FIGS. 22 through 31 show consecutive reference tables also unique to the illustrative embodiment;

FIGS. 32 through 37 show consecutive conversion tables further unique to the illustrative embodiment; and

FIG. 39 is a flowchart demonstrating a specific coding procedure particular to the illustrative embodiment.

### DESCRIPTION OF THE PREFERRED EMBODIMENT

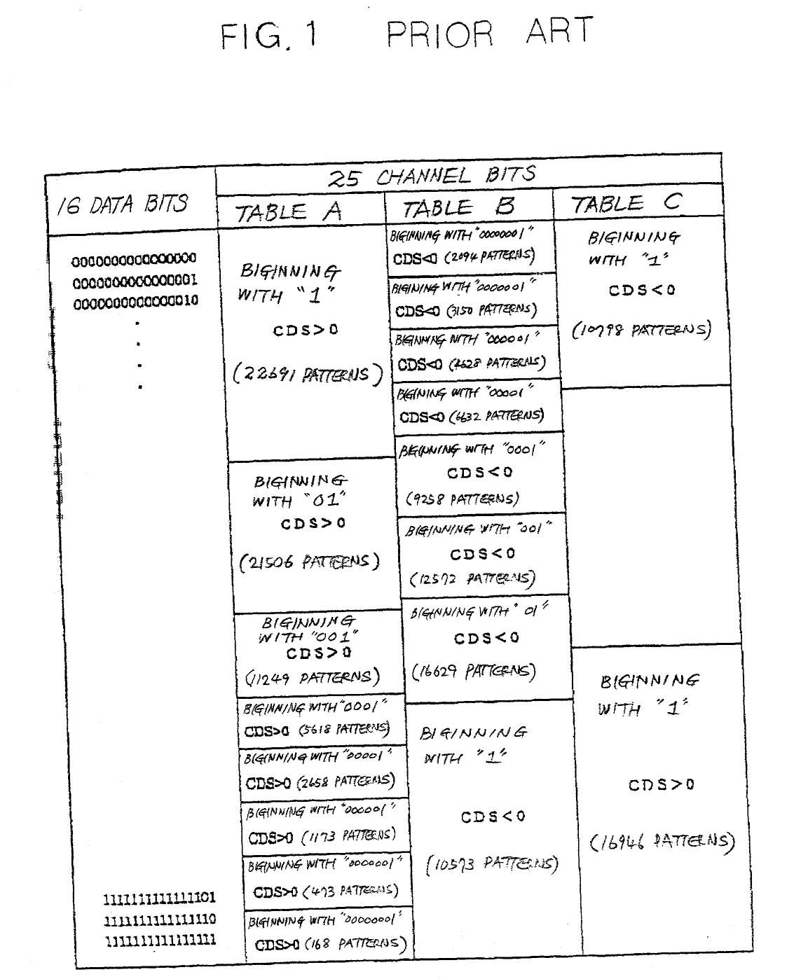

To better understand the present invention, brief reference will be made to a conversion table included in the code converter that is disclosed in Japanese Patent Laid-Open Publication No. 2000-183750 mentioned earlier. As shown in FIG. 1, to convert sixteen data bits to twenty-five channel bits, the conversion table consists of three different kinds of conversion tables A, B and C each assigning a particular bit pattern to all possible patterns of sixteen data bits, i.e., 2¹⁶=65,536 different patterns. The code converter optimally selects one of the conversion tables A, B and C to limit the minimum and maximum numbers of continuous bits of the resulting pattern of twenty-five channel bits to two and eight, respectively. Such a code converter achieves the merit of the (1,7) coding scheme and reduces the demerit of the same, i.e., reduces a DC component. This kind of scheme, however, has the problem discussed earlier left unsolved.

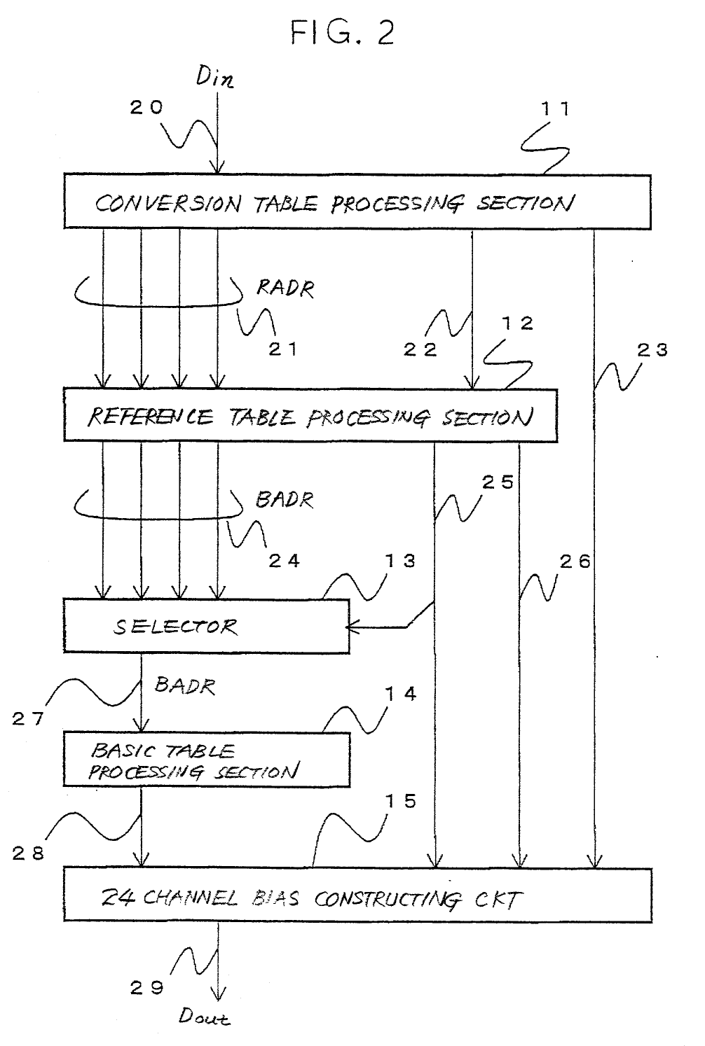

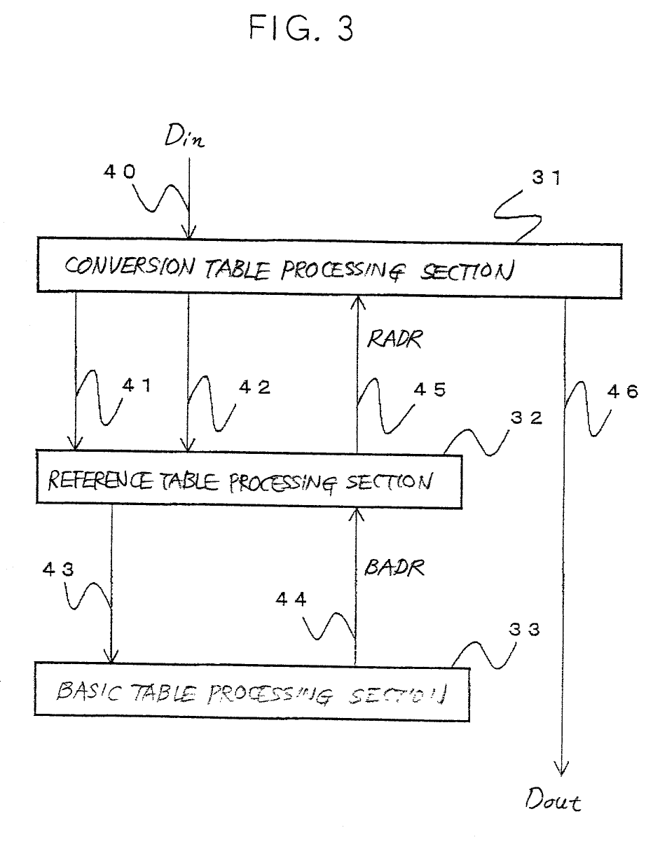

Referring to FIGS. 2 and 3, a code converter embodying the present invention will be described. Briefly, the illustrative embodiment includes a basic table for converting m-bit data to n-bit channel bits greater in number than the m-bit data. The basic table lists a number of patterns defined on the basis of bit patterns required of codes and sufficiently smaller than 2^{m}. Calculations are effected with the basic table in order to convert all data of m data bits to n channel bits. FIGS. 2 and 3 respectively show coding circuitry and decoding circuitry constituting the illustrative embodiment; m and n are assumed to be “16” and “24”, respectively.

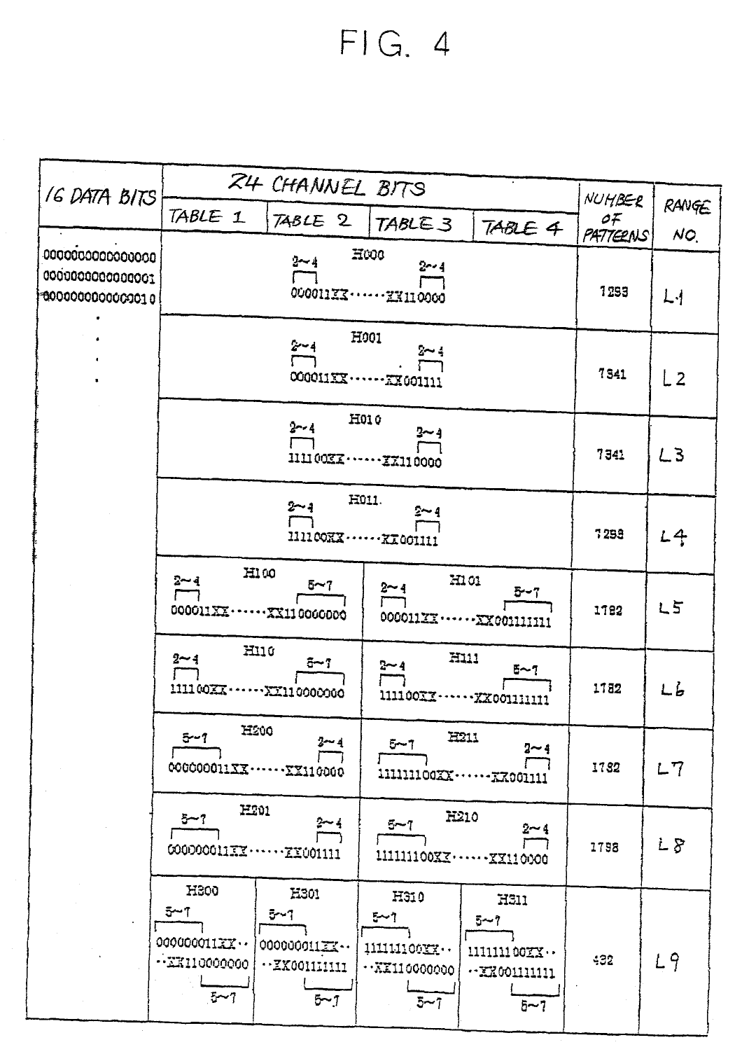

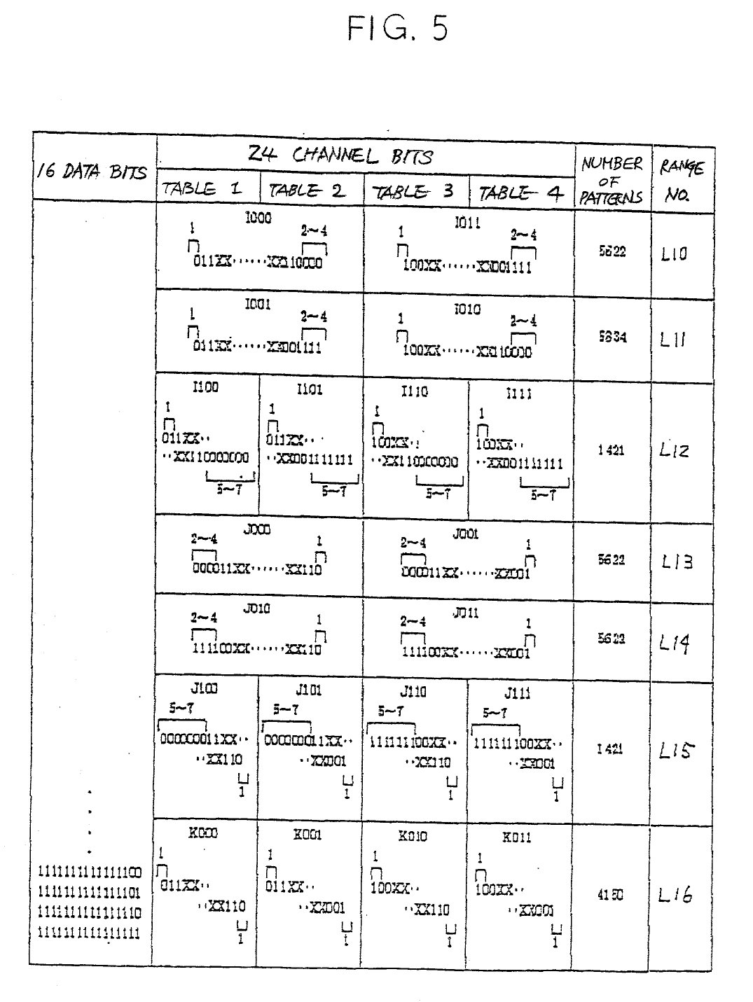

FIGS. 4 and 5 show in combination a table applicable to the conversion table of the illustrative embodiment. Assume a code converter of the type converting m (sixteen) data bits to n (twenty-four) channel bits and therefore dealing with 2^{m} different patterns. Also, assume that the 2^{m} patterns each have i kinds of ranges with respect to a relation between the total number j of particular ranges and the number of range numbers Lk (1≦k≦j). The conversion table therefore consists of j=16 conversion table groups to which range numbers L1 through L16 are respectively assigned.

More specifically, as shown in FIGS. 4 and 5, the patterns of sixteen data bits are classified into range numbers L1 through L16 by the characteristic of the pattern. Further, the range numbers L1, L2, L3 and L4 each include one kind (group) of table or subtable. The range numbers L5, L6, L7, L8, L10, L11, L13 and L14 each include two kinds (groups) of tables or subtables. Further, the range numbers L9, L12, L15 and L16 each include four kinds (groups) of conversion tables or subtables. The number of kinds of subtables is therefore thirty-six in total. This classification allows the conversion table to be efficiently used for the checking of the previously stated conditions and other purposes.

The conversion table has the following sixteen ranges and thirty-six subtables:

| | | |
|---|---|---|
| range #L1: | 7,293 patterns | one subtable H000 |
| range #L2: | 7,341 patterns | one subtable H001 |
| range #L3: | 7,341 patterns | one subtable H010 |
| range #L4: | 7,293 patterns | one subtable H011 |
| range #L5: | 1,782 patterns | two subtables H100, |
| | | H101 |
| range #L6: | 1,782 patterns | two subtables H110, |
| | | H111 |
| range #L7: | 1,782 patterns | two subtables H200, |
| | | H211 |
| range #L8: | 1,798 patterns | two subtables H201, |
| | | H210 |
| range #L9: | 432 patterns | four subtables |
| | | H300, H301, H310, |
| | | H311 |
| range #L10: | 5,622 patterns | two subtables I000, |
| | | I011 |
| range #L11: | 5,834 patterns | two subtables I001, |
| | | I010 |
| range #L12: | 1,421 patterns | four subtables |
| | | I100, I101, I110, |
| | | I111 |
| range #L13: | 5,622 patterns | two subtables J000, |
| | | J001 |
| range #L14: | 5,622 patterns | two subtables J010, |
| | | J011 |
| range #L15: | 1,421 patterns | four subtables |
| | | J100, J101, J110, |
| | | J111 |
| range #L16: | 4,150 patterns | four subtables |
| | | K000, K001, K010, |
| | | K011 |

Coding using the above conversion table provides codes with the minimum inversion interval of 1.33 Tb, the maximum inversion interval of 5.33 Tb and the sensing window width of 0.67 Tb, which are the merits of the (1, 7) coding scheme, as stated earlier. Further, the number of 2 Ts to appear at the channel bit interval Ts is reduced. Moreover, a DC-free code whose DSV approaches zero in absolute value can be implemented with high probability, thereby reducing the demerit of the (1, 7) coding scheme. However, to convert the sixteen data bits shown in FIGS. 4 and 5 to twenty-four channel bits, there must be used a conversion table capable of dealing with as many as 65536 (1¹⁶) different data bit patterns.

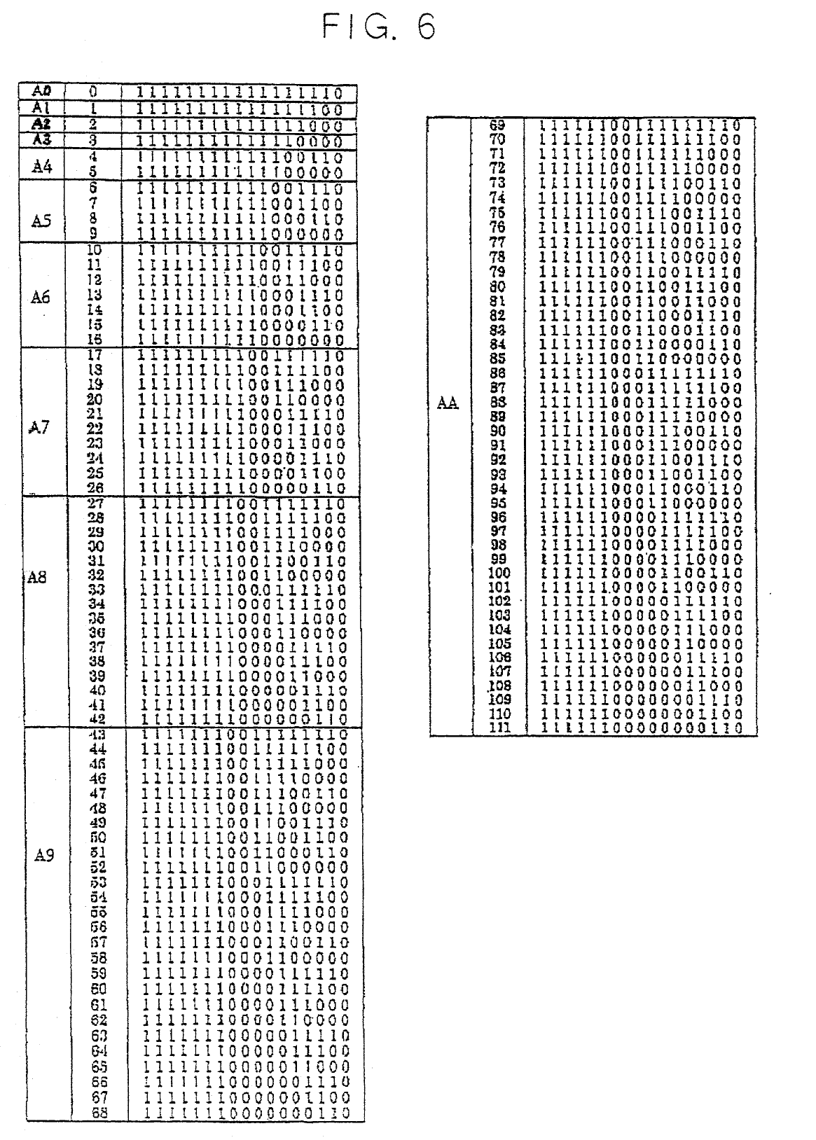

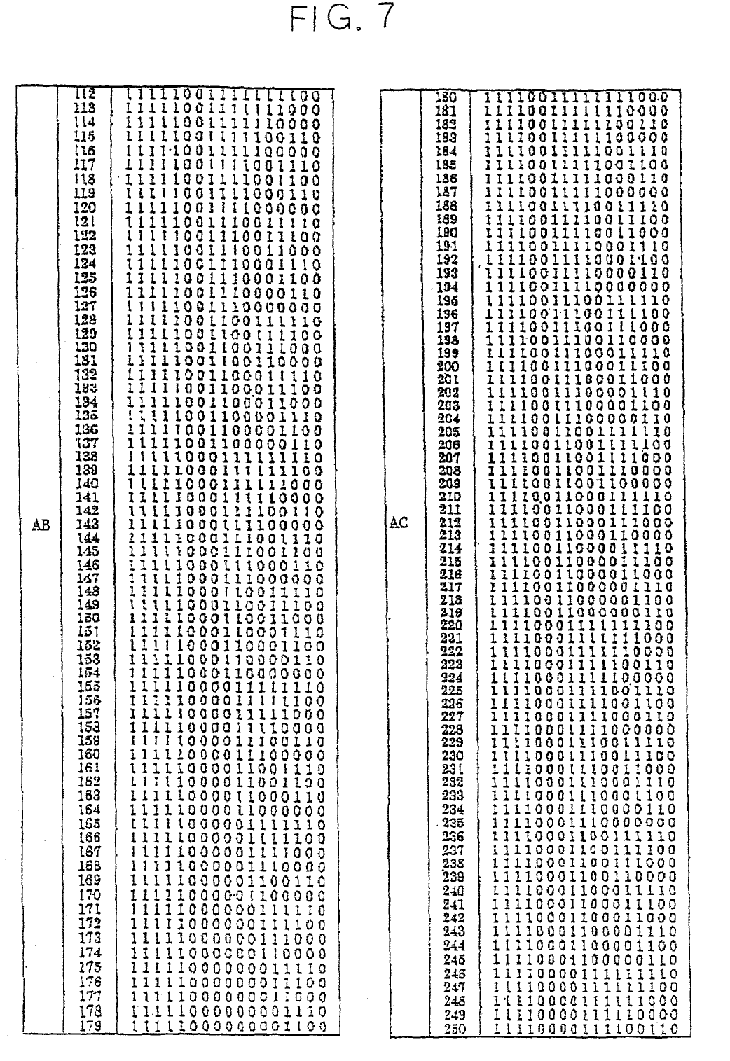

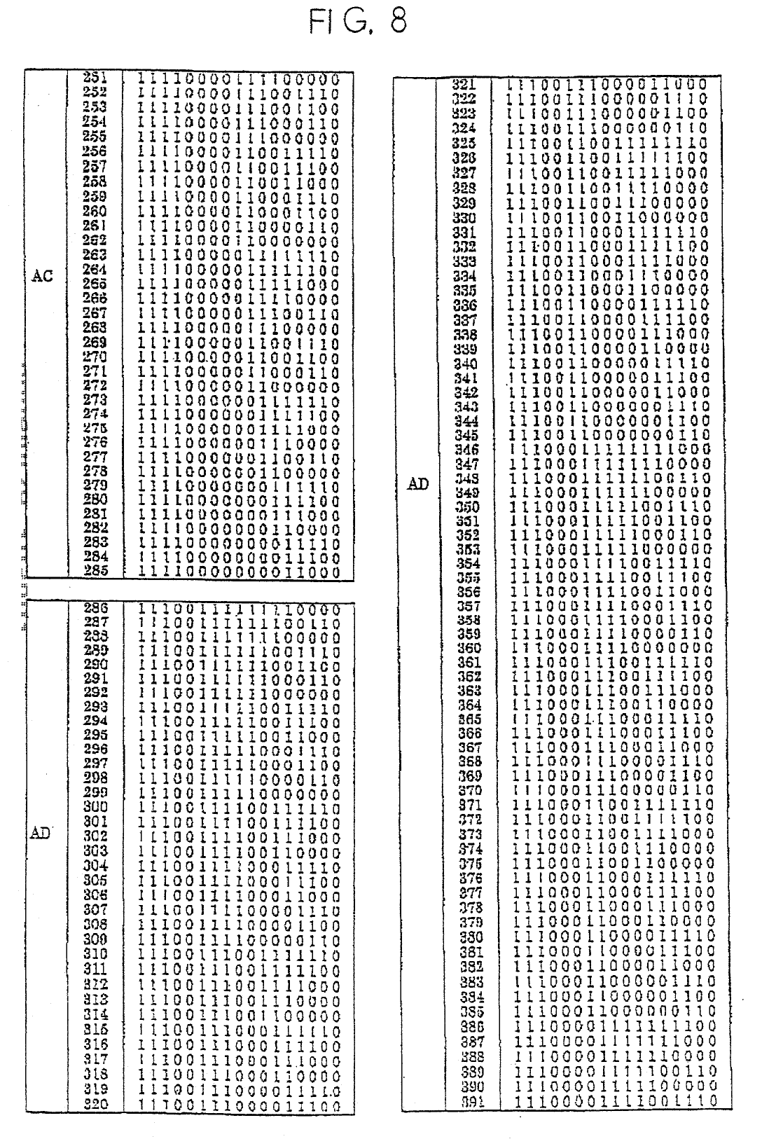

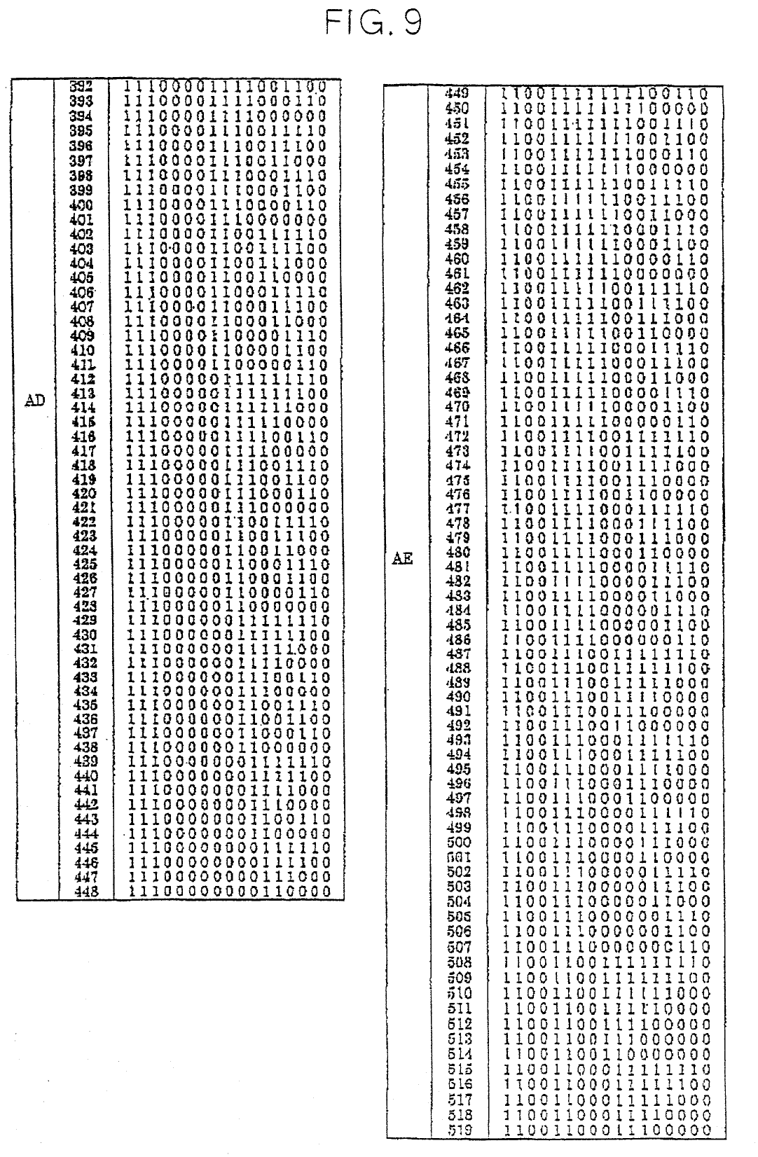

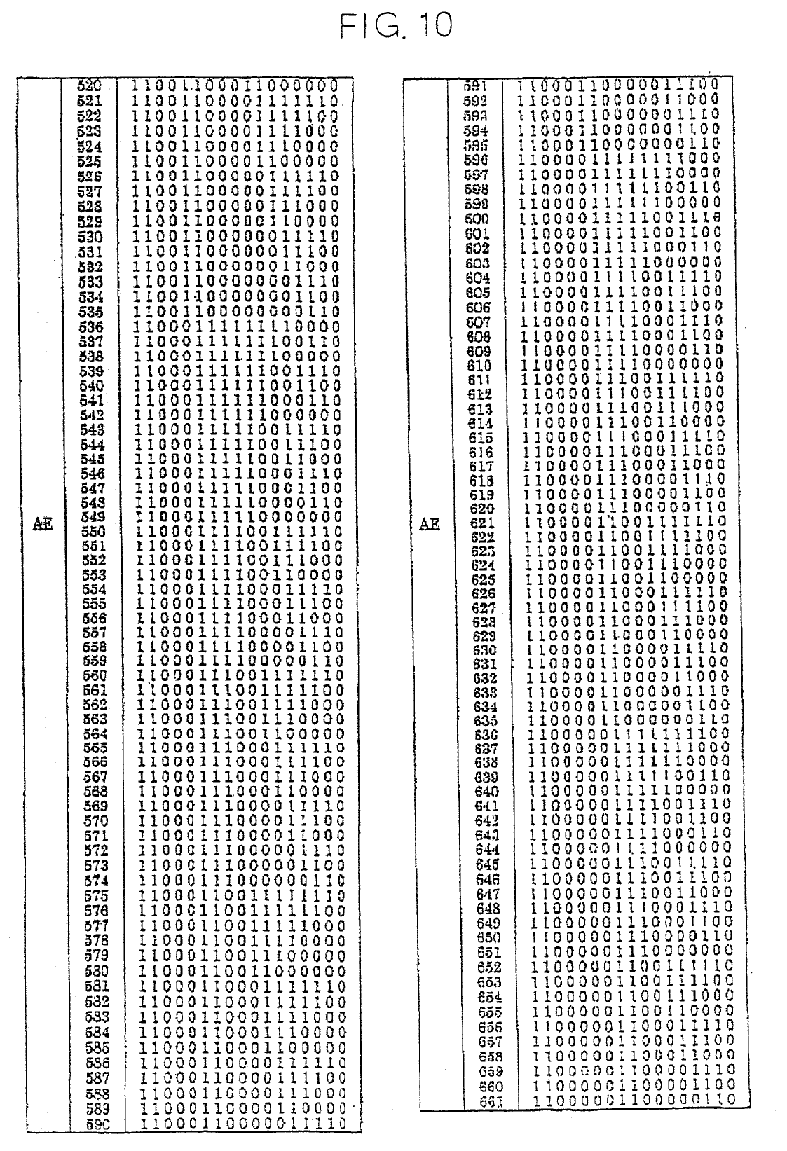

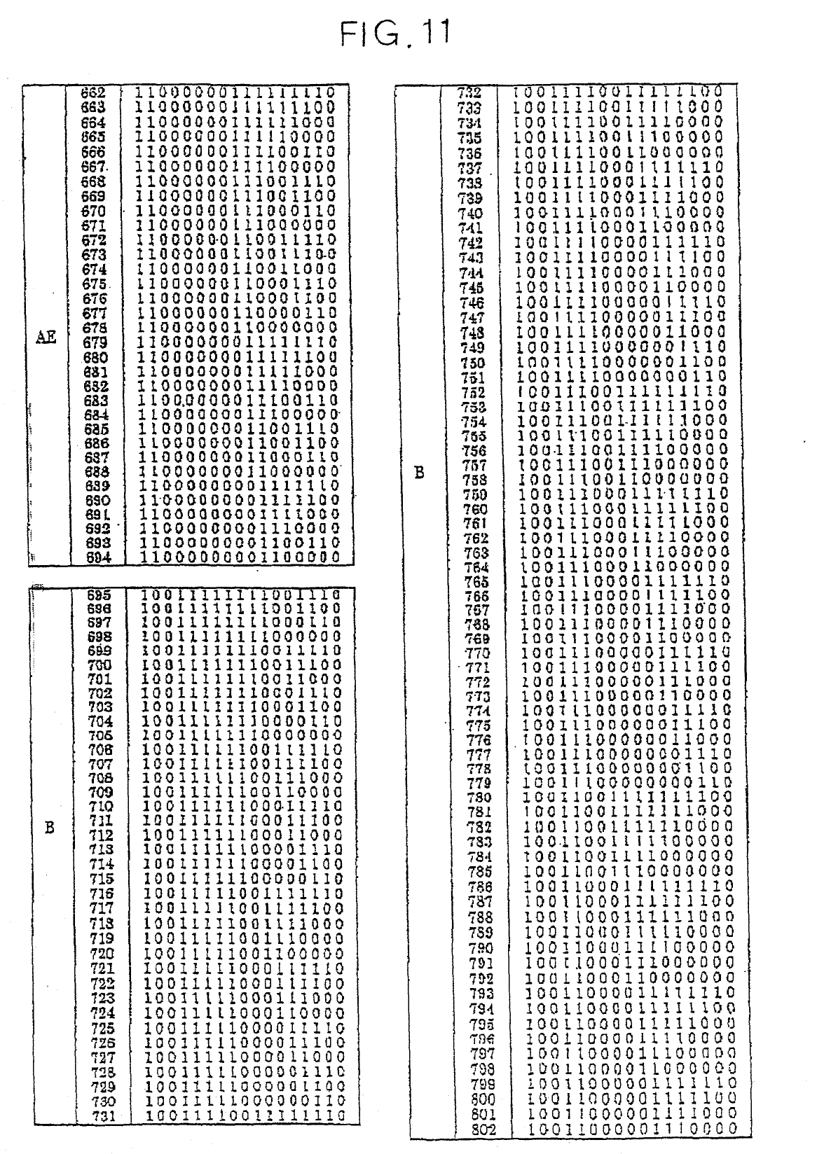

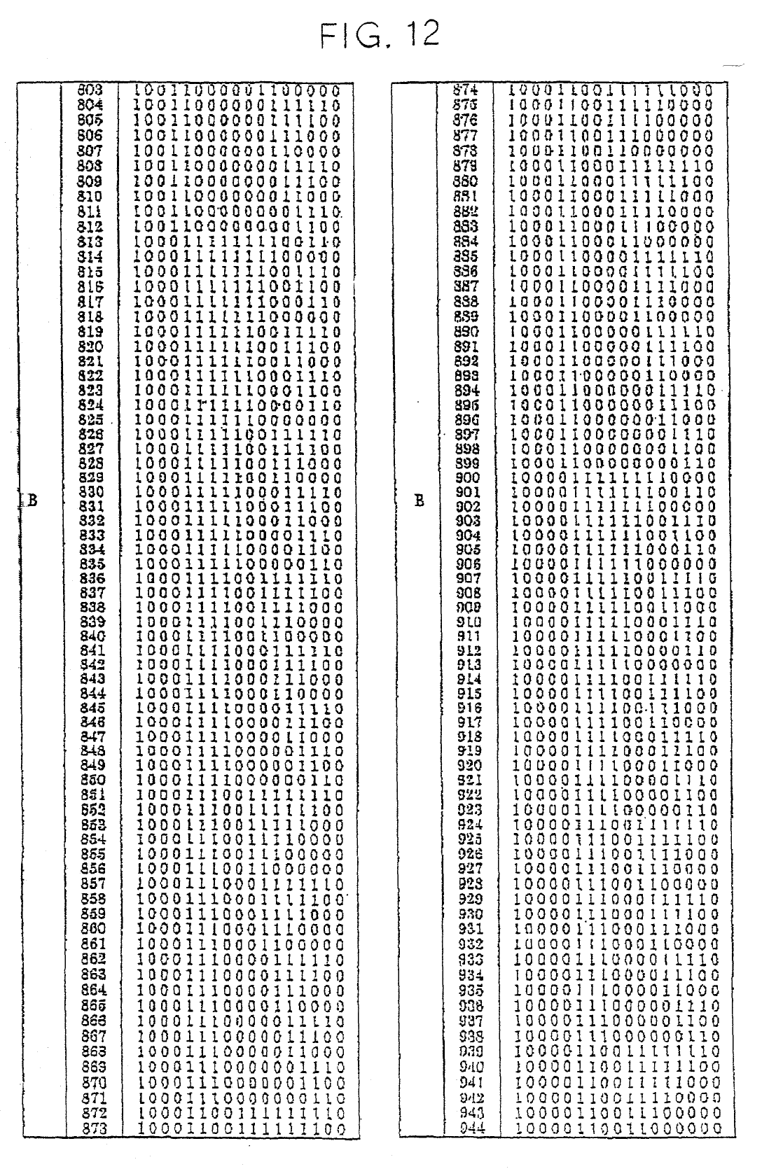

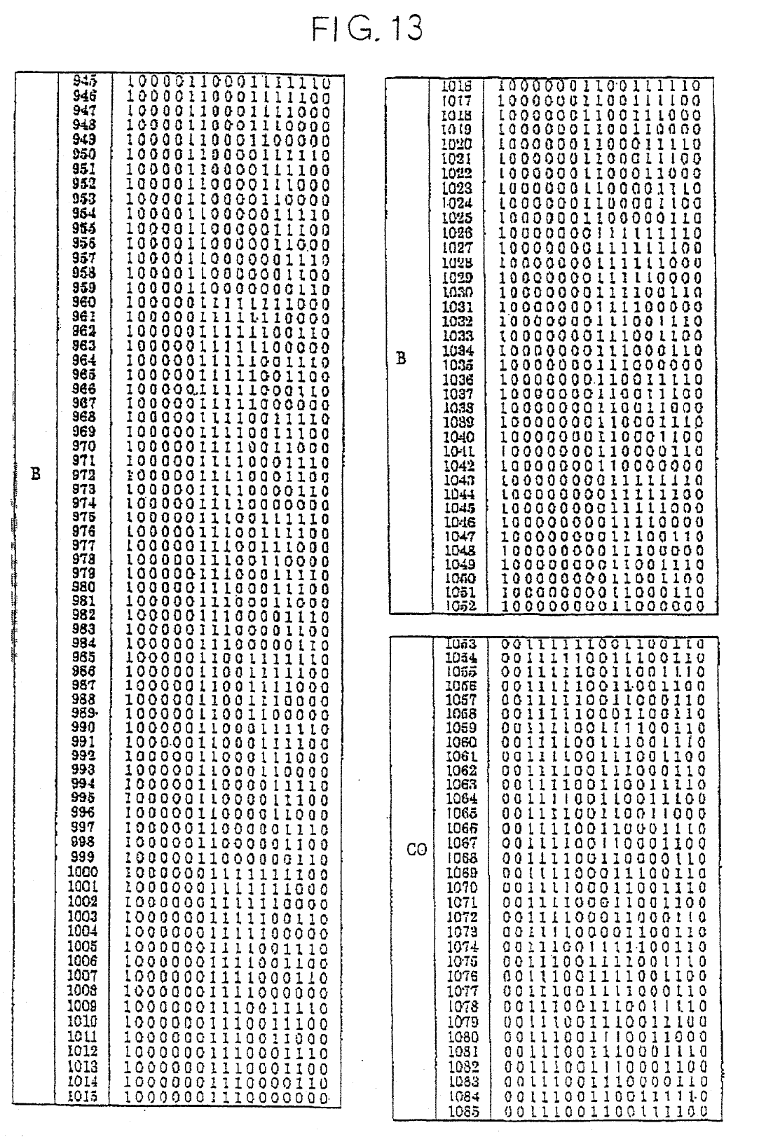

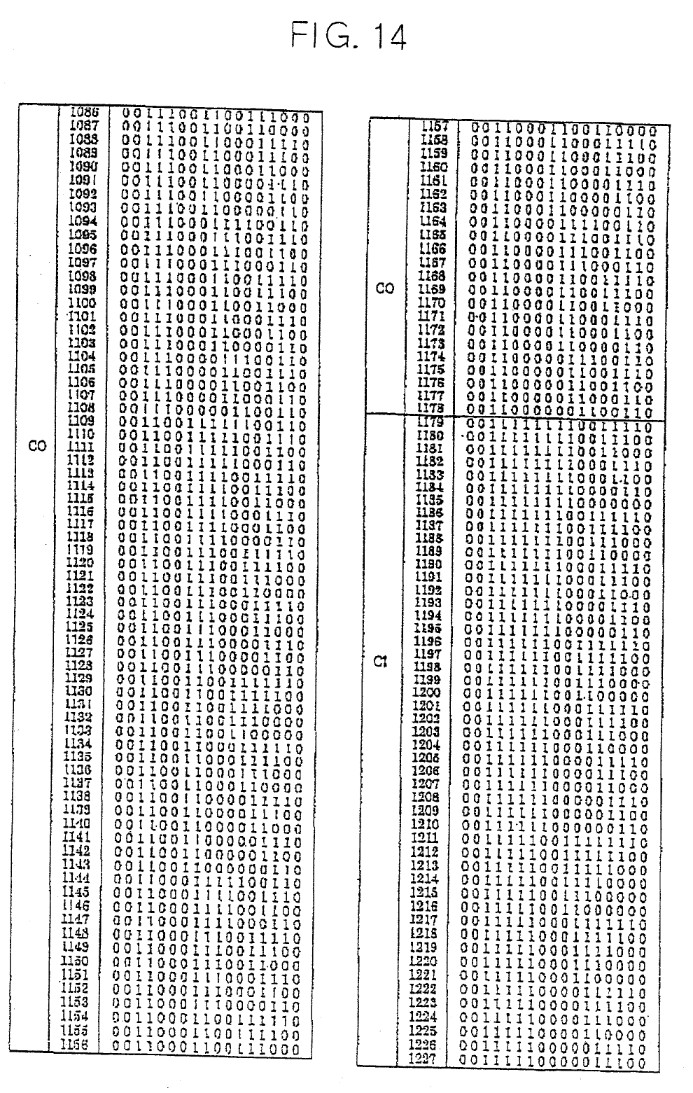

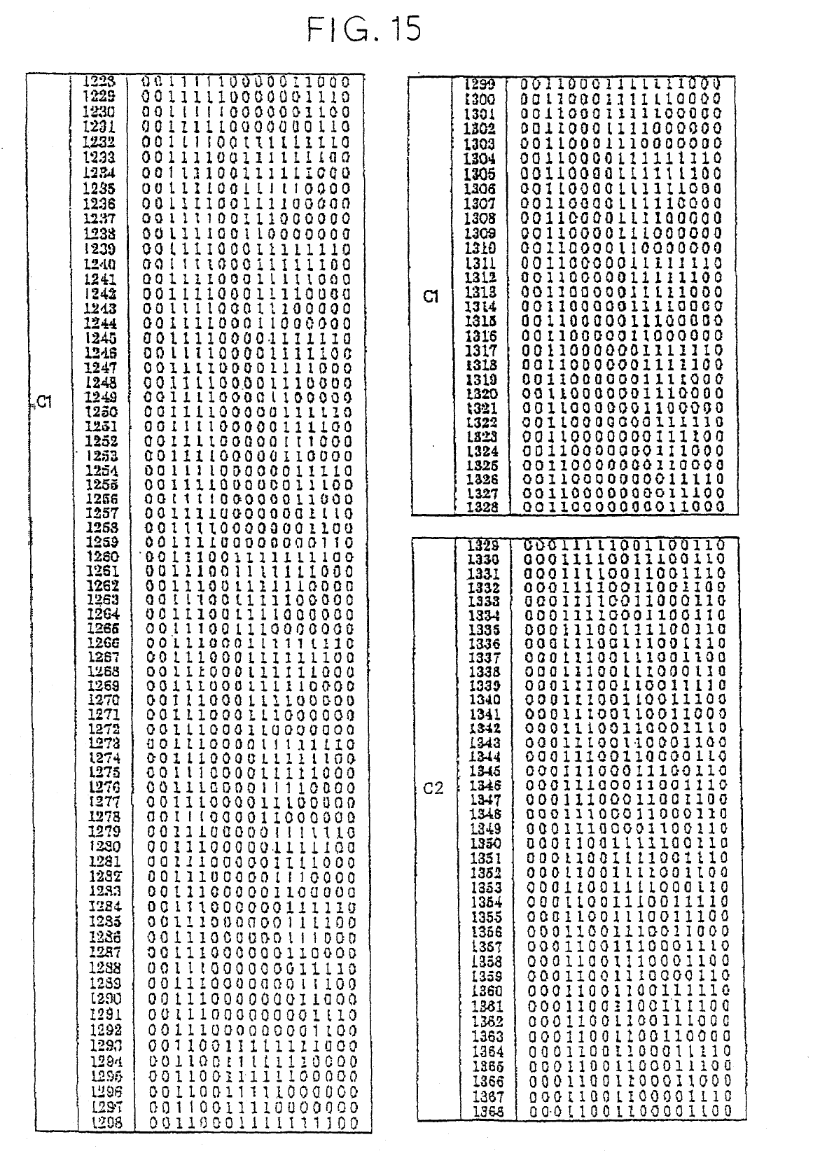

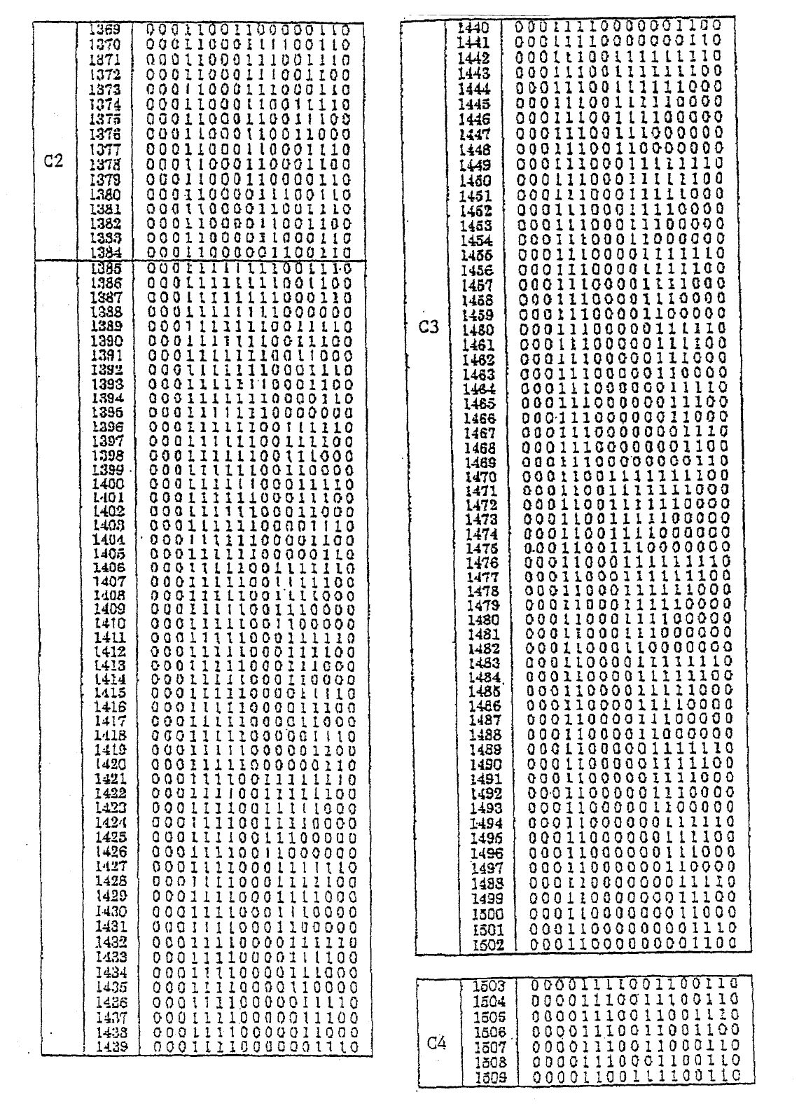

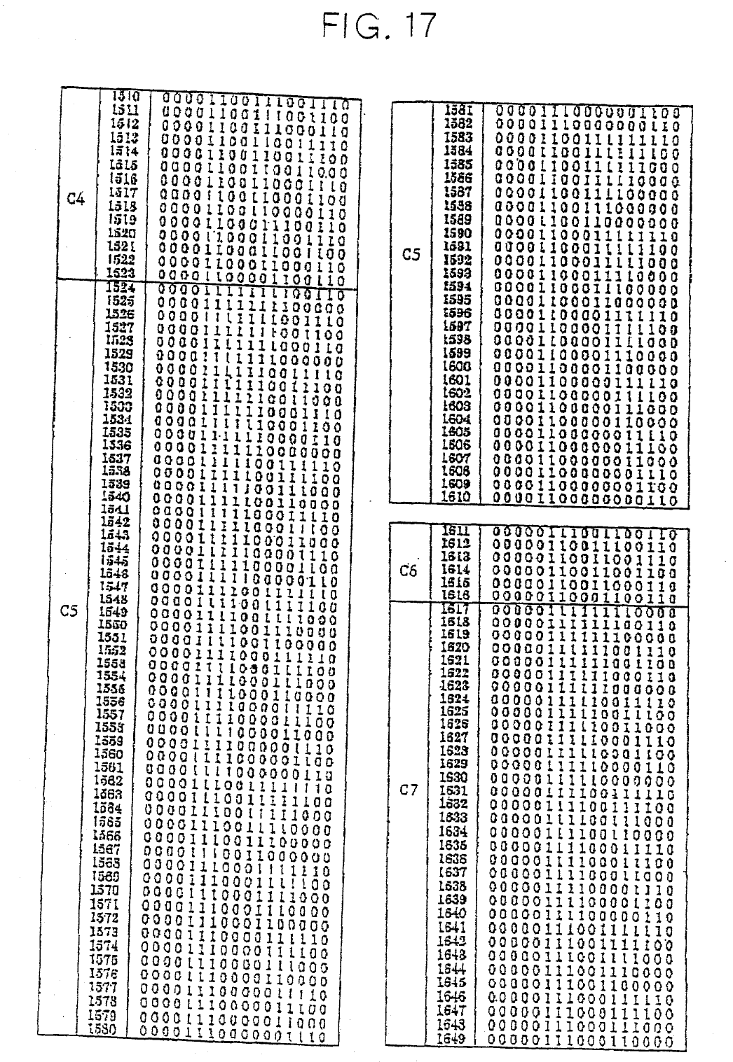

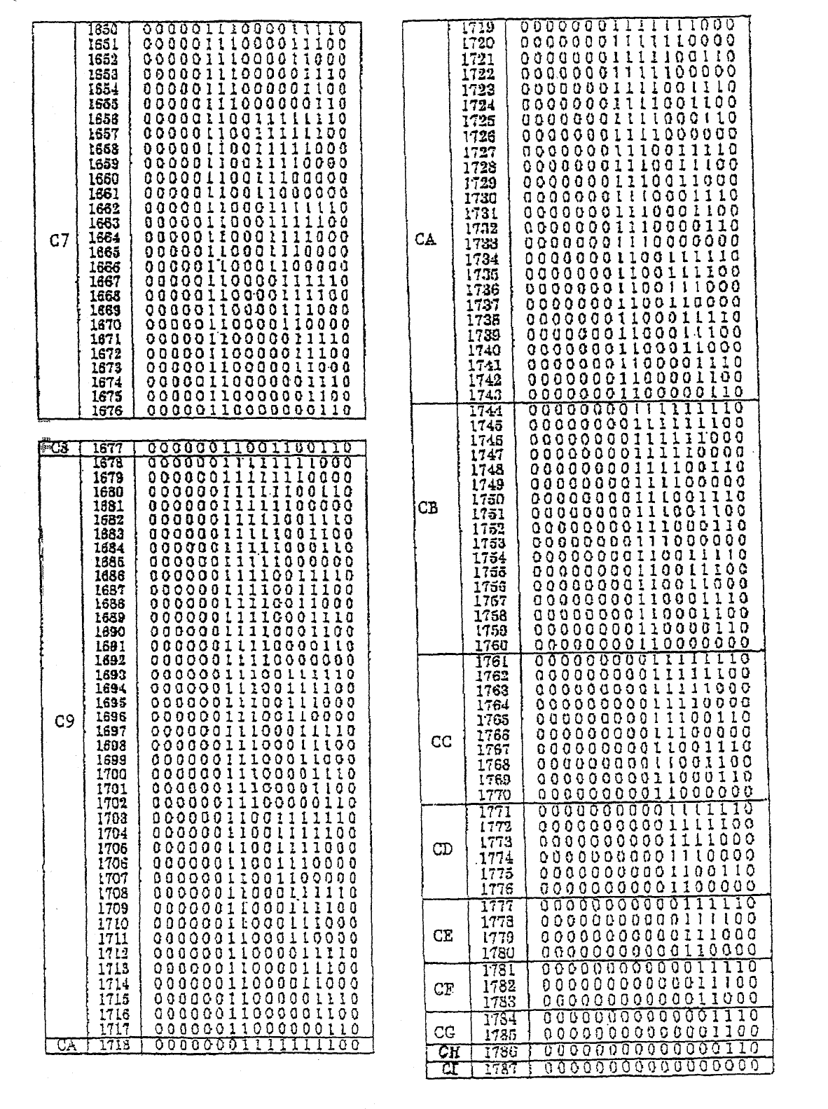

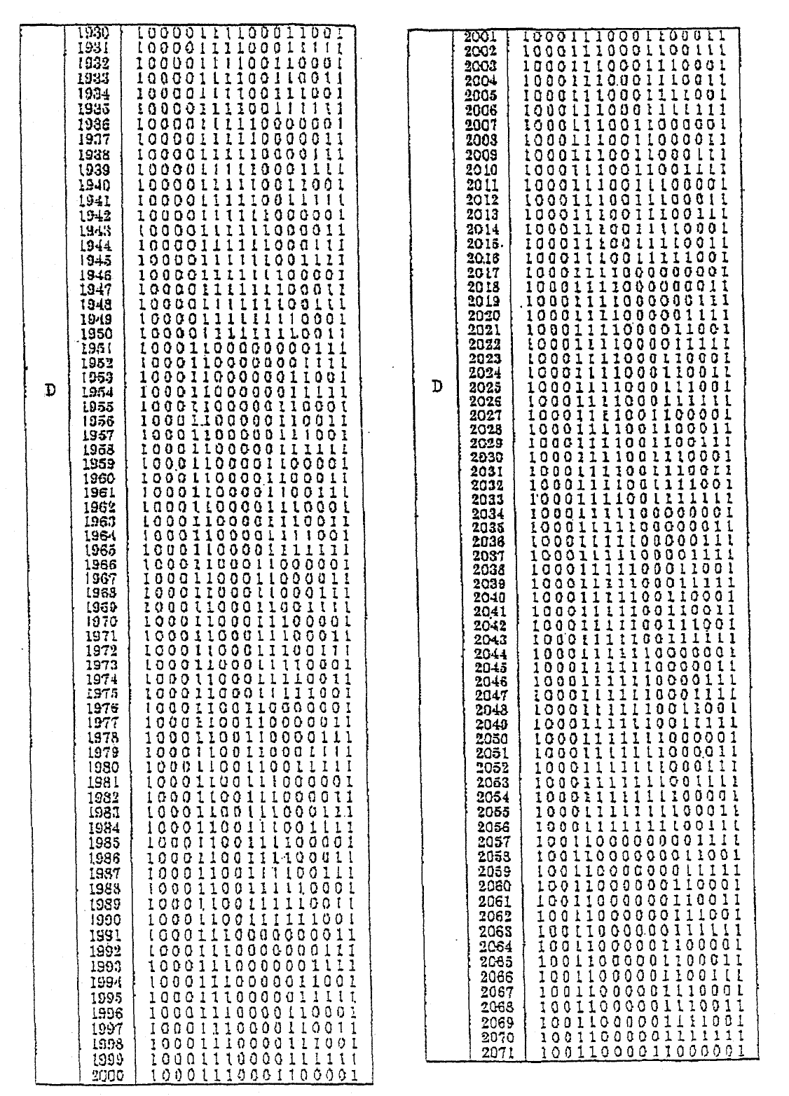

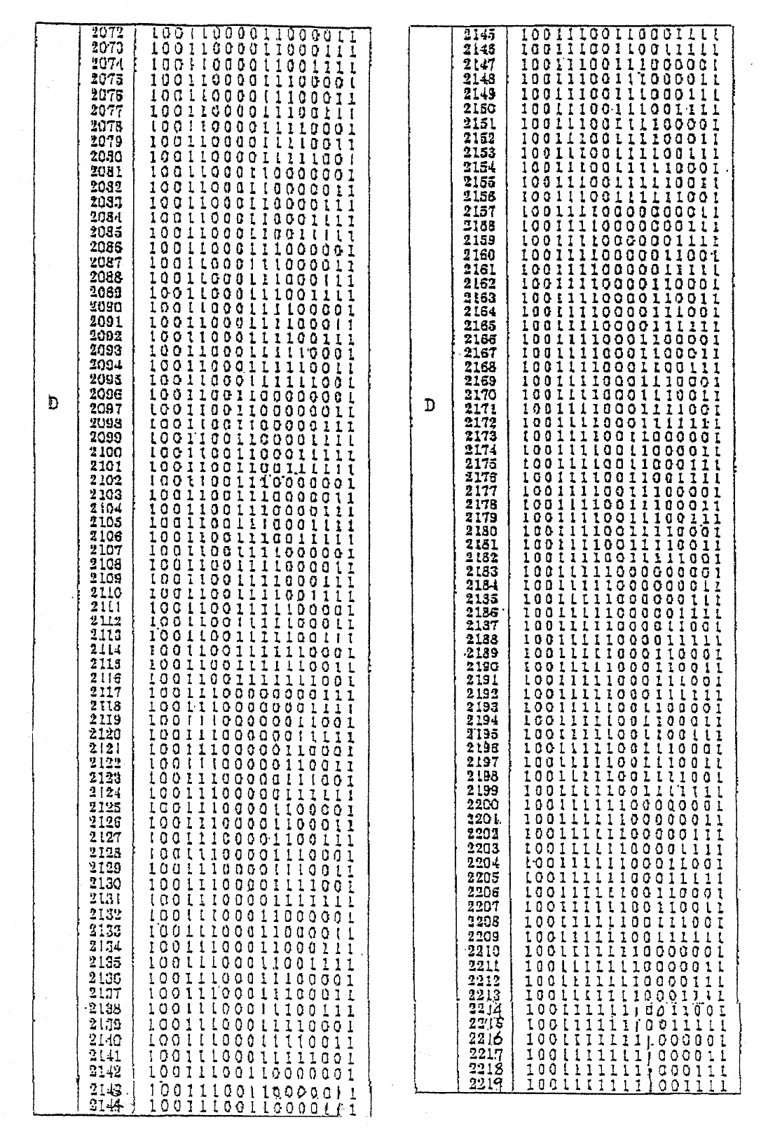

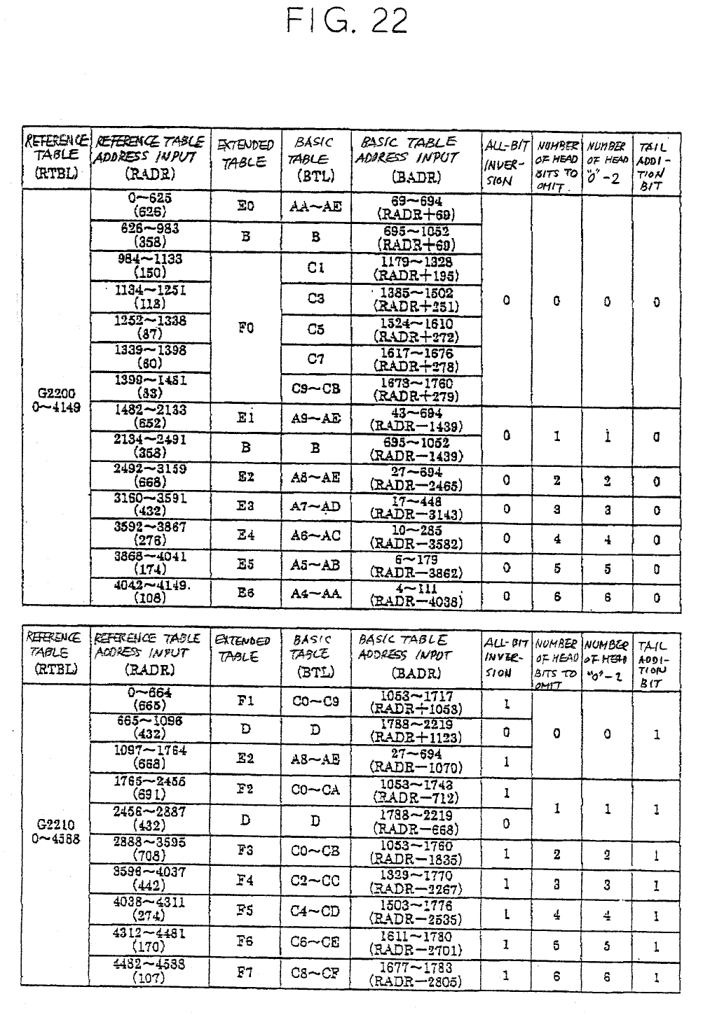

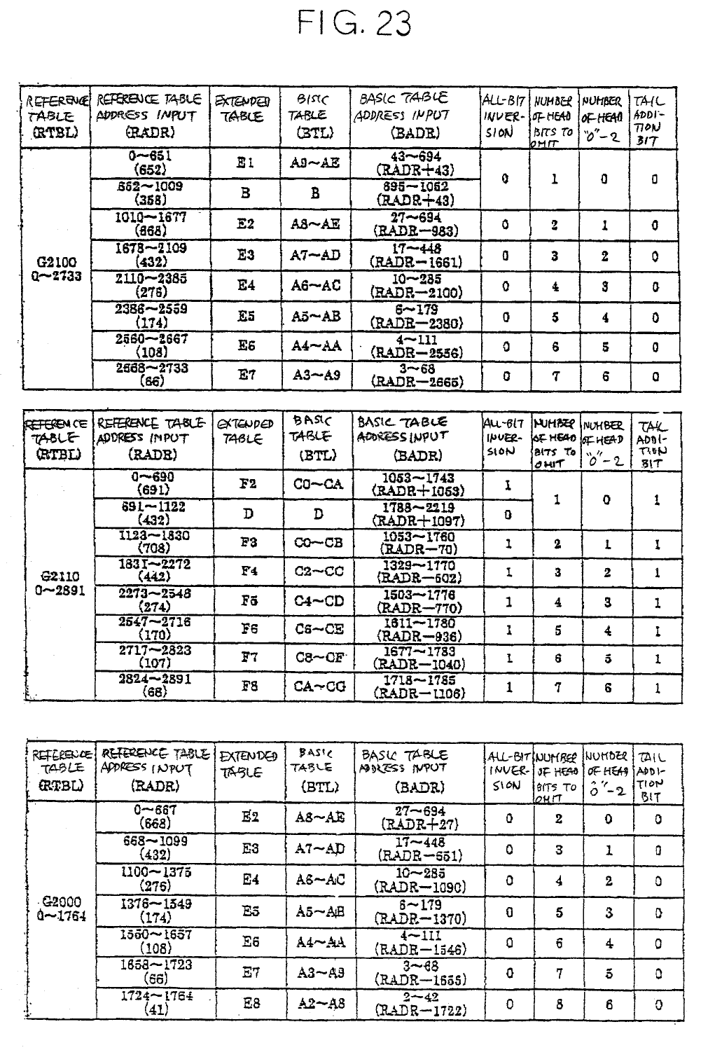

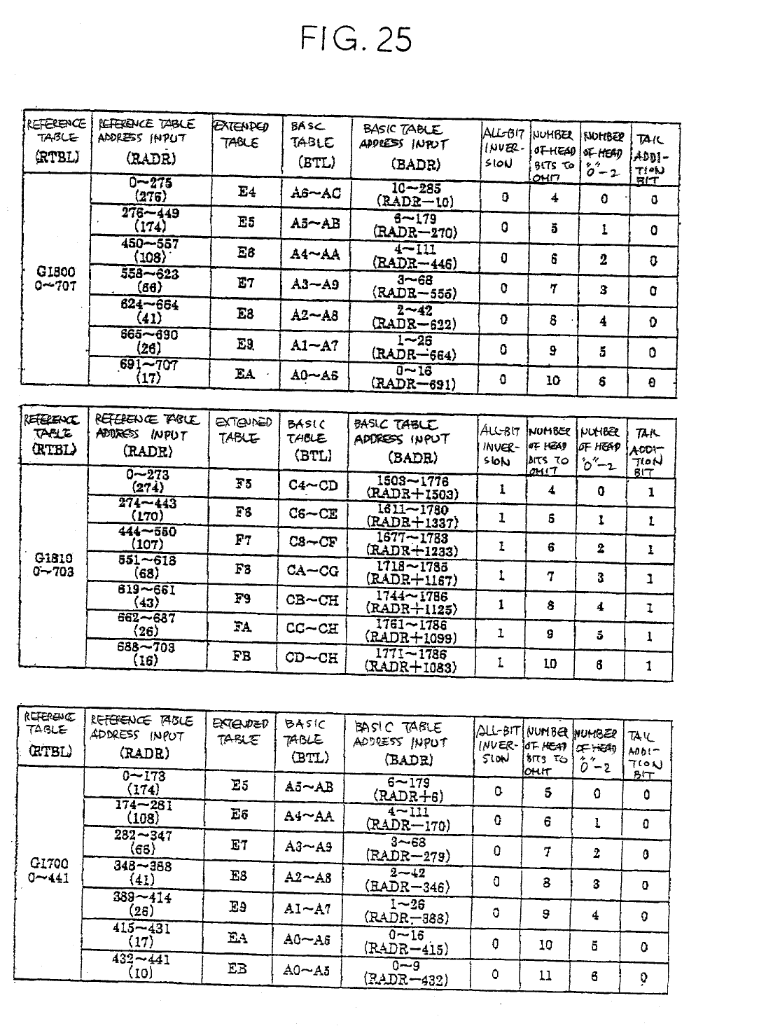

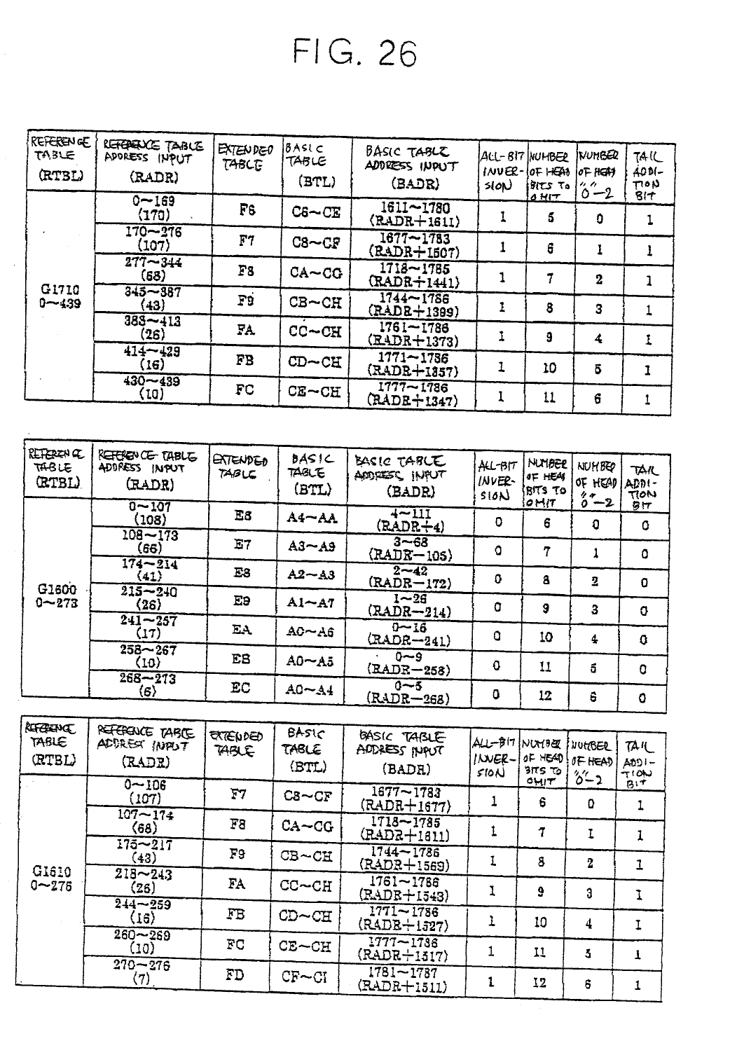

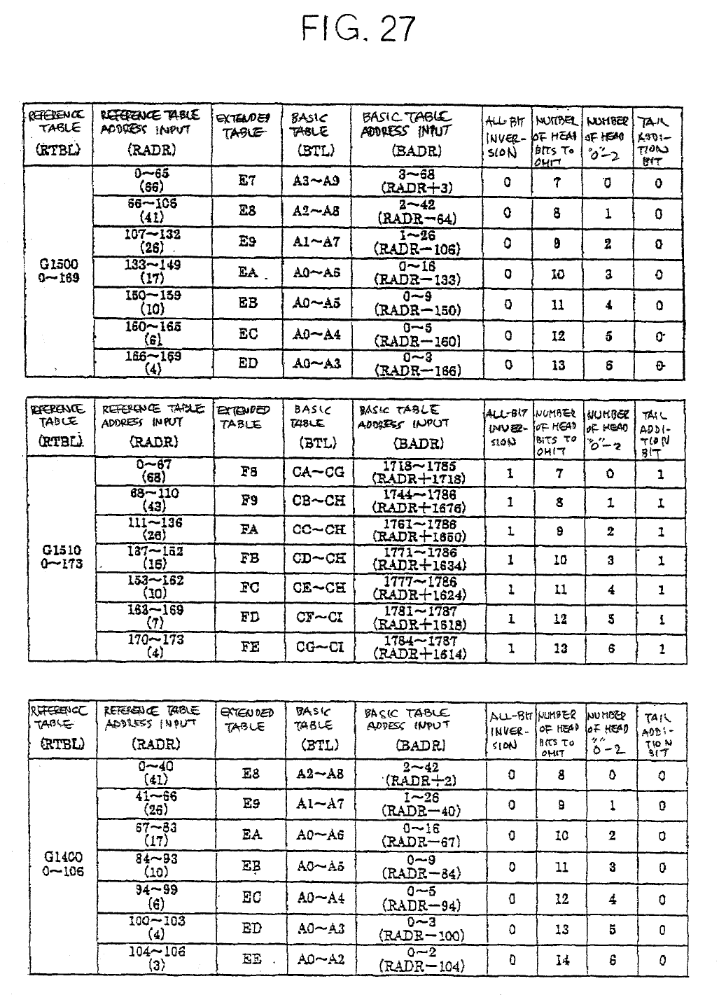

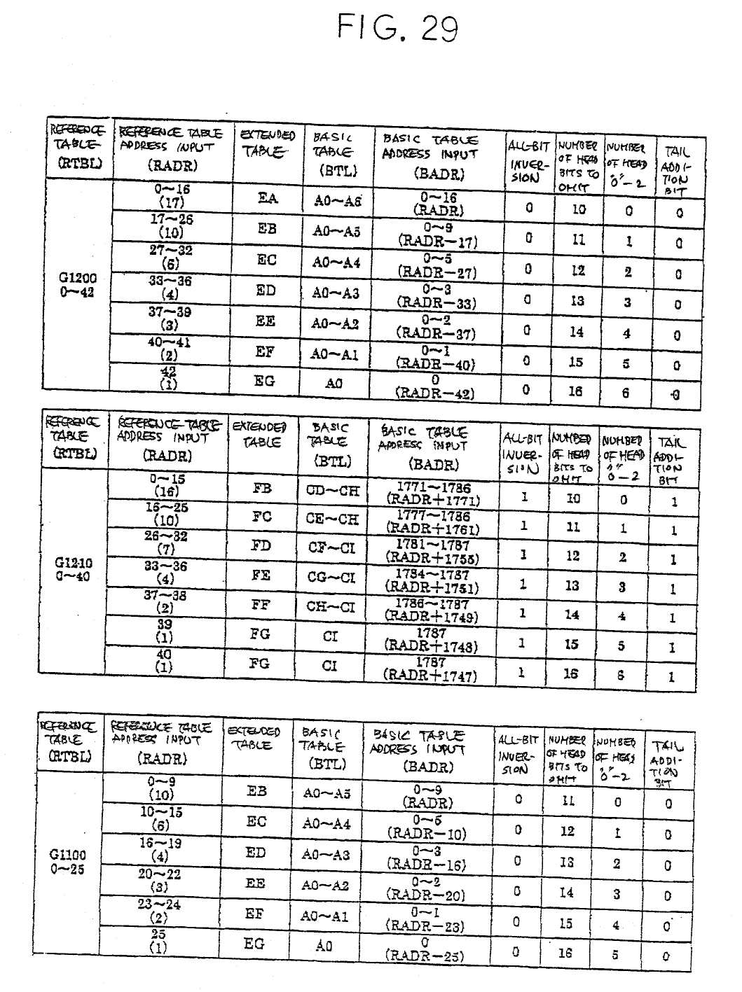

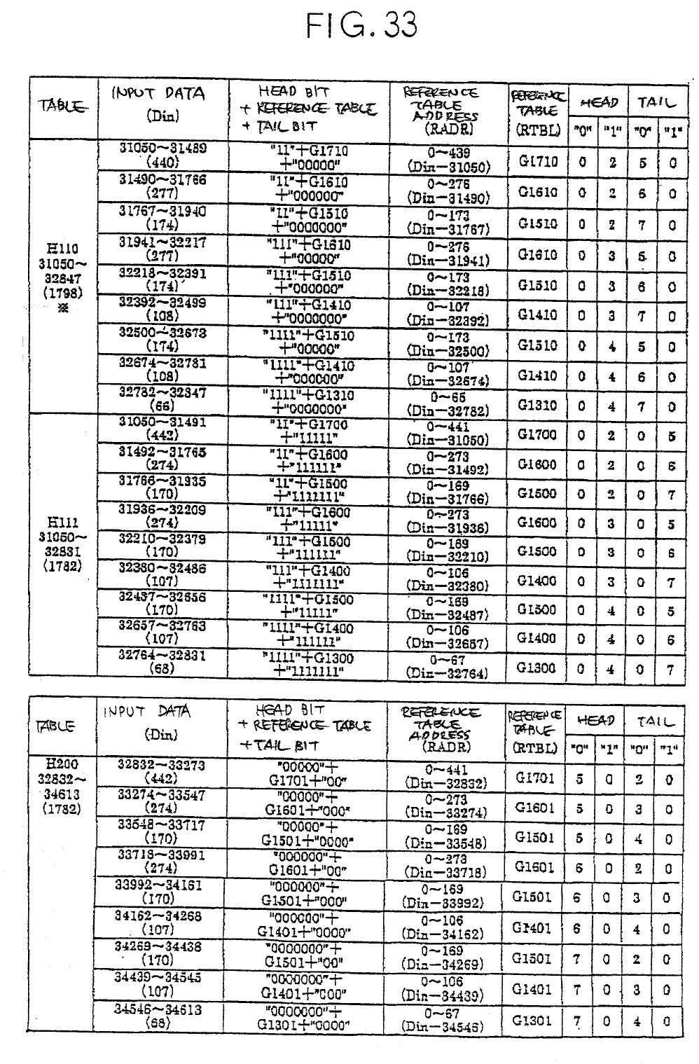

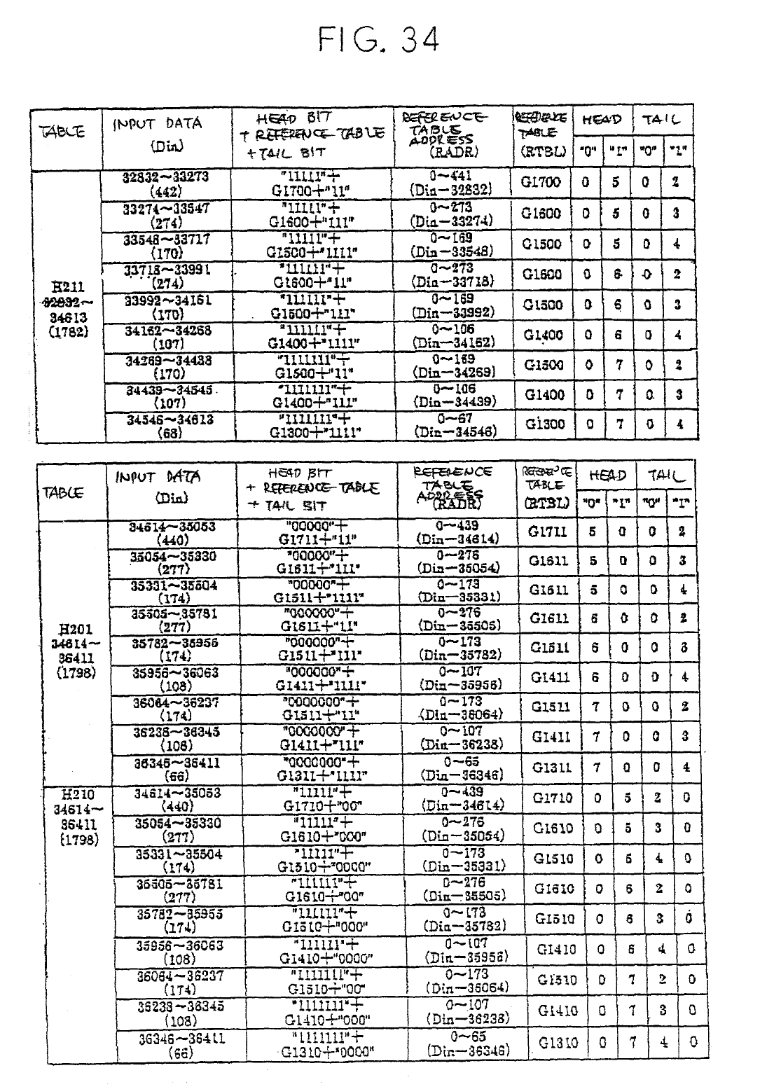

The illustrative embodiment uses a basic table, which will be described with reference to FIGS. 6 through 21 later, listing 2220 data-bit patterns far smaller in number than 65536 patterns. FIGS. 22 through 30 show a reference table derived from the basic table of the illustrative embodiment. Further, FIGS. 31 through 38 show a conversion table also unique to the illustrative embodiment.

As shown in FIG. 2, the coding circuitry of the illustrative embodiment is generally made up of a conversion table processing section 11, a reference table processing section 12, a selector 13, a basic table processing section 14, and a twenty-four channel bits constructing circuit 15.

FIGS. 31 through 38 show a specific conversion table to be dealt with by the conversion table processing section 11 and indicating a relation between the range of input data and a reference table. Basically, the conversion table, like the table shown in FIGS. 4 and 5, classifies patterns of input sixteen data bits into the ranges L1 through L16. Again, the maximum number of subtables is four. However, assume that sixteen data bits are integrated into 2220 patterns produced by applying preselected limitations to seventeen bits. Such 2220 patterns are shown in FIGS. 6 through 21 specifically.

On receiving input data (Din) 20, which are sixteen data bits, the conversion table processing section 11 compares the input data 20 with the conversion tables and selects corresponding data information by using the Din # as a key. The processing section 11 delivers a reference table address (RADR) 21 and a reference table information signal 22 included in the data information to the reference table processing section 12. At the same time, the processing section 11 delivers a bit addition control signal 23 also contained in the data information to the twenty-four channel bit constructing circuit 15. Assume that up to four different subtables are prepared for a single pattern of input data as in the case of FIGS. 3 and 4.

Reference tables to be dealt with by the reference table processing section 12 are produced from extension tables shown in FIGS. 22 through 30 specifically. As shown, the number of bits and the conversion of the head bit or the tail bit are designated in each extension table, thereby preparing twenty-six different G tables.

The reference table processing section 12 received the reference table address (RADR) 21 and reference table information signal 22 compares the data with the reference table and select data information corresponding to the input data. The processing section 12 then feeds a basic table address (BADR) 24 and a select signal 25 to the selector 13. At the same time, the processing section 12 feeds the select signal 25 and a bit conversion control signal 26 to the twenty-four channel bits constructing circuit 15.

The basic table processing section 14 stores 2,220 unique patterns in total that are easy to search. Specifically, in each pattern, one bit is added to sixteen bits of data to produce seventeen bits, which is smaller than twenty-four bits. The 2220 patterns are therefore far smaller than 65536 different input data patterns (2¹⁶). In the basic table, 2220 patterns are classified into four tables A through D. Further, the tables A and C are subdivided into fifteen subtables and nineteen subtables, respectively, preparing thirty-six subtables in total.

An extended table is prepared to allow a particular pattern to be searched for on the subdivided table A or C. The extended table consists of the tables A through D and tables E and F respectively prepared by shifting the subtables of the tables A and C by one subtable. The tables E and F have seventeen subtables each. The extended table therefore has thirty-eight subtables in total.

The basic table processing section 14 selects, based on the basic table address (BADR) 24 received from the selector 13, at least one seventeen-bit data pattern as basic table output data 28. The processing section 14 then delivers the basic table output data 28 to the twenty-four channel bits constructing circuit 15.

Usually, the twenty-four channel bits constructing circuit 15 receives a plurality of basic table output data 28 based on the select signal 25. The circuit 15 therefore constructs twenty-four channel bits in accordance with the bit addition control signal 23 and bit conversion control signal 26 output from the conversion table processing section 11 and reference table processing section 12, respectively. As for a plurality of channel bits, the circuit 15 selects a channel bit having priority with respect to the inversion interval rule or selects, if priority is the same, a channel bit having a smaller DSV in absolute value. The circuit 15 outputs the resulting twenty-four channel bits as output data (Dout) 25.

As shown in FIG. 3, the decoding circuitry that decodes twenty-four channel bits to sixteen data bits is generally made up of a conversion table processing section 31, a reference table processing section 32, and a basic table processing section 33.

The conversion table processing section 31 deals with the conversion tables shown in FIGS. 31 through 38 in the reverse way. Specifically, on receiving input data (Din) 40, which are twenty-four channel bit data, the processing section 31 counts the head bits and tail bits and then searches the reference table to which the input data Din belongs. The processing section 31 delivers reference data 41 of twenty-two bits to ten bits and a reference table indication signal 42 of five bits to the reference table processing section 32.

The reference table processing section 32 deals with the conversion tables shown in FIGS. 22 through 30 in the reverse way. Specifically, the processing section 32 inputs the reference data 41 in the reference table designated by the reference table indication signal 42. The processing section 32 then feeds the resulting basic table data bits 43 to the basic table processing section 33.

The basic table processing section 33 uses the basic tables shown in FIGS. 6 through 21. Specifically, the processing section 33 received the basic table data bits 43 delivers a basic table address (BADR) 44 corresponding to the data to the reference table processing section 32.

The reference table processing section 32 calculates a reference table address (RADR) 45 from the basic table address (BADR) 44 and feeds the address (RADR) 45 to the conversion table processing section 31.

The conversion table processing section 32 calculates sixteen data bits from the reference table address (RADR) 45 and delivers the calculated data bits as output data (Dout) 46.

The tables unique to the illustrative embodiment will be described more specifically hereinafter.

First, reference will be made to FIGS. 6 through 21 for describing the basic table that is the fundamental feature of the illustrative embodiment. As shown, for easy coding and decoding, the basic table generates 2220 seventeen-bit patterns under four different conditions. The basic table consists of the previously mentioned tables (groups) A through D including thirty-six subtables. The four different conditions mentioned above are as follows.

Condition 1

A pattern does not include a portion where nearby bits are inverse to each other except for the head portion and tail portion, e.g., “ . . . 101 . . . ” or “ . . . 010 . . . ”.

Condition 2

As for the head portion of seventeen bits, a pattern begins with “00”, “01” or “11” other than “01”. As for the tail portion, the pattern may end with any one of “00”, 01”, “10” and “11”.

Condition 3

The maximum number of identical bits continuously appearing in a pattern is eight except for the head portion and tail portion. Any number of identical bits may continuously appear in the head portion. The maximum number of identical bits is seven in the tail portion.

For example, a pattern “11111111100 . . . ” in which nine consecutive bits are “1” in the head portion is selected. On the other hand, a pattern “0011111111100 . . . ” in which “1” continuously appears over nine bits in the intermediate portion is not selected. Further, a pattern “ . . . 110000000011 . . . ” in which “0” continuously appears over eight bits in the intermediate portion is selected. However, a pattern “ . . . 1100000000 . . . ” in which “0” continuously appears over eight bits in the tail portion is not selected. A pattern whose seventeen bits all are “0” is selected as an exception.

Condition 4

In a pattern beginning with “11” or “10”, the numbers of “0” and “1” adjoining each other, i.e., the number of times of inversion for implementing NRZ recording is limited to five or less. As for a pattern beginning with “00”, the number of times of inversion is limited to six or less.

2220 patterns to be described hereinafter are selected under the conditions 1 through 4 to thereby prepare the basic table. The basic table is stored in a ROM (Read Only Memory) or similar memory. In this manner, the illustrative embodiment needs only 2220 patterns, which is far smaller than 65536 patterns.

The table A lists the following 695 patterns each beginning with “11” and ending with “0”:

1 pattern “11111111111111110”

A0

1 pattern beginning with “1111111111111110”

A1

1 pattern beginning with “111111111111110”

A2

1 pattern beginning with “11111111111110”

A3

2 patterns beginning with “1111111111110”

A4

4 patterns beginning with “111111111110”

A5

7 patterns beginning with “11111111110”

A6

10 patterns beginning with “1111111110”

A7

16 patterns beginning with “111111110”

A8

26 patterns beginning with “11111110”

A9

43 patterns beginning with “1111110”

AA

68 patterns beginning with “111110”

AB

106 patterns beginning with “11110”

AC

163 patterns beginning with “1110”

AD

246 patterns beginning with “110”

AE

The table B lists 358 patterns each beginning with “10” and ending with “0”.

The table C lists the following 735 patterns each beginning with “00” and ending with “0”:

126 patterns beginning with “001” and including six times of inversion

C0

150 patterns beginning with “001” and including five times of inversion or less

C1

56 patterns beginning with “0001” and including six times of inversion or less

C2

118 patterns beginning with “0001” and including five times of inversion or less

C3

21 patterns beginning with “00001” and including six times of inversion

C4

87 patterns beginning with “0000” and including five times of inversion or less

C5

6 patterns beginning with “000001” and including six times of inversion

C6

60 patterns beginning with “000001” and including five times of inversion or less

C7

1 pattern beginning with “0000001” and including six times of inversion

C8

40 patterns beginning with “0000001” and including five times of inversion or less

C9

26 patterns beginning with “00000001”

CA

17 patterns beginning with “000000001”

CB

10 patterns beginning with “0000000001”

CC

6 patterns beginning with “00000000001”

CD

4 patterns beginning with “000000000001”

CE

3 patterns beginning with “0000000000001”

CF

2 patterns beginning with “00000000000001”

CG

1 pattern beginning with “000000000000001”

CH

1 pattern “000000000000000000”

CI

The table D lists 432 patterns each beginning with “10” and ending with “1”.

The extended table is made up of thirty-eight subtables that are the combinations of the tables A through D of the basic table. The subtables, which list 9,034 patterns in total, are as follows.

table A: continuous arrangement of A0, A1, A2, A3, A4, A5, A6, A7, A8, A9, AA, AB, AC, AD and AE; 695 patterns

table B: B only; 358 patterns

table C: continuous arrangement of C0, C1, C2, C3, C4, C5, C6, C7, C8, C9, CA, CB, CC, CD, CE, CF, CG, CH and CI; 735 patterns

table D: D only; 432 patterns

table E0: AA, AB, AC, AD and AE; 626 patterns

table E1: A9, AA, AB, AC, AD and AE; 652 patterns

table E2: A8, A9, AA, AB, AC, AD and AE; 668 patterns

table E3: A7, A8, A9, AA, AB, AC and AD; 432 patterns

table E4: A6, A7, A8, A9, AA, AB and AC; 276 patterns

table E5: A5, A6, A7, A8, A9, AA and AB; 174 patterns

table E6: A4, A5, A6, A7, A8, A9 and AA; 108 patterns

table E7: A3, A4, A5, A6, A7, A8 and A9; 66 patterns

table E8: A2, A3, A4, A5, A6, A7 and A8; 41 patterns

table E9: A1, A2, A3, A4, A5, A6 and A7; 26 patterns

table EA: A0, A1, A2, A3, A4, A5 and A6; 17 patterns

table EB: A0, A1, A2, A3, A4 and A5; 10 patterns

table EC: A0, A1, A2, A3 and A4; 6 patterns

table ED: A0, A1, A2 and A3; 4 patterns

table EE: A0, A1 and A2; 3 patterns

table EF: A0 and A1; 2 patterns

table EG: A0 only; 1 pattern

table F0: C1, C3, C5, C7, C9, CA and CB; 498 patterns

table F1: C0, C2, C2, C3, C4, C5, C6, C7, C8 and C9; 665 patterns

table F2: C0, C1, C2, C3, C4, C5, C6, C7, C8, C9 and CA; 691 patterns

table F3: C0, C1, C2, C3, C4, C5, C6, C7, C8, C9, CA and CB; 708 patterns

table F4: C2, C3, C4, C5, C6, C7, C8, C9, CA, CB and CC; 442 patterns

table F5: C4, C5, C6, C7, C8, C9, CA, CB, CC and CD; 274 patterns

table F6: C6, C7, C8, C9, CA, CB, CC, CD and CE; 170 patterns

table F7: C8, C9, CA, CB, CC, CD, CE and CF; 107 patterns

table F8: CA, CB, CC, CD, CE, CF and CG; 68 patterns

table F9: CB, CC, CD, CD, CF and CH; 43 patterns

table FA: CC, CD, CE, CF, CG and CH; 26 patterns

table FB: CD, CE, CF, CG and CH; 16 patterns

table FC: CE, CF, CG and CH; 10 patterns

table FD: CF, CG, CH and CI; 7 patterns

table FE: DG, CH and CI; 4 patterns

table FF: CH and CI; 2 patterns

table FG: CI only; 1 pattern

Referring to FIGS. 22 through 30, the reference table (RTBL) will be described in detail. The reference table is produced from the extended table described above. First, columns included in the reference table will be described.

In the reference table, the first column shows reference table numbers (G numbers) and the ranges of input addresses below the reference table numbers. As for a reference table G2200, for example, a range of addresses “0-4149” designating the table G2200 is shown below “G2200”. Among the four bits of the G number, the first two bits are representative of the number of subject bits while the third bit is representative of a last addition bit. The last bit is “0” without exception.

The second column shows reference table address inputs (RADR) corresponding to the extended and basic tables. For example, when the extended table E0 is selected on the reference table G2200, the range and the total number of RADRs are “0-625” and 626, respectively.

The third column and fourth column show the extended tables and basic tables (BTBL). AA-AE, for example, indicates the basic tables AA, AB, AC, AD and AE.

The fifth column shows basic table address (BADR) outputs. In the reference table G2200, for example, the fifth column shows a relation between the basic table address (BADR) “169-694” and the reference table address (RADR); BADR=RADR+69.

The sixth column shows a bit indicative of all-bit inversion. When this bit is ONE, the basic table output is immediately inverted.

The seventh column shows the number of head bits to be omitted. For example, if the number of bits is “2”, then two head bits of the basic table output are omitted after inversion/non-inversion.

The eighth column shows “number of head “0”−2”, i.e., the number of head bits to which “0” should be added. In practice, this column shows the addition of “0” and “0011” to the above bits. For example, if this column is “0”, then bits “0011” are added to the head of the data whose head bits are omitted, but “0” is not added. If the column is “1”, then bits “00011” are added to the head of the data. Further, if the column is “2”, then bits “000011” are added to the head of the data. In addition, if the column is “n”, then “0” is added to the data over n consecutive bits to the head of the data and immediately followed by the bits “0011”.

The ninth column shows a bit to be added to the tail bit of the data having bits added to its head. If this column is “0”, then “0” is added to the tail bit. If the column is “1”, then “1” is added to the tail bit of the above data. Stated another way, the tail bit of the data with added bits is repeated in order to increase the number of bits by one.

Twenty-six reference tables are prepared by designating the number of bits and the head/tail bit, as will be described hereinafter.

A reference table G2200 lists 4,150 twenty-two-bit patterns in total covering the addresses 0 through 4149 and beginning and ending with “0”. The 4,150 patters are as follows:

1,482 patterns produced by adding “0011” to the heads of E0, B and F0

1,010 patterns produced by omitting one head bit of E1 and B and then adding “00011”

668 patterns produced by omitting two head bits of E2 and then adding “000011”

432 patterns produced by omitting three head bits of E3 and then adding “0000011”

276 patterns produced by omitting four head bits of E4 and then adding “00000011”

174 patterns produced by omitting five head bits of E5 and then adding “000000011”

108 patterns produced by omitting six head bits of E6 and then adding “0000000011”

twenty-two-bit patterns produced by further adding “0” to the tail bit of the above twenty-one-bit patterns

A reference table G2210 lists 4,589 twenty-two-bit patterns covering the addresses 0 through 4588 and beginning with “0” and ending with “1”. The 4,589 patterns are as follows:

665 patterns produced by inverting all bits of F1 and then adding “0011” to the head

432 patterns produced by adding “0011” to the head of D

668 patterns produced by inverting all bits of E2 and then adding “0022” to the head

691 patterns produced by inverting all bits of F2, then omitting one head bit, and then adding “00011”

432 patterns produced by omitting one head bit of D and then adding “00011”

708 patterns produced by inverting all bits of F3, then omitting two head bits, and then adding “000011”

442 patterns produced by inverting all bits of F4, then omitting three head bits, and then adding “0000011”

274 patterns produced by inverting all bits of F5, then omitting four head bits, and then adding “00000011”

170 patterns produced by inverting all bits of F4, then omitting five head bits, and then adding “000000011”

107 patterns produced by inverting all bits of F7, then omitting six head bits, and then adding “0000000011”

twenty-two-bit patterns produced by further adding “1” to the above twenty-one-bit patterns

A reference table G2100 lists 2734 twenty-one-bit patterns covering the addresses 0 through 2733 and beginning and ending with “0”. The 2734 patterns are as follows:

1010 patterns produced by omitting one head bit of E1 and B and then adding “0011”

668 patterns produced by omitting two head bits of E2 and adding “00011”

432 patterns produced by omitting three head bits of E3 and then adding “000011”

276 patterns produced by omitting four head bits of E4 and then adding “0000011”

174 patterns produced by omitting five head bits of E5 and then adding “00000011”

108 patterns produced by omitting six head bits of E6 and then adding “000000011”

66 patterns produced by omitting seven head bits of E7 and then adding “0000000011”

twenty-one-bit patterns produced by further adding “0” to the above twenty-bit patterns

A reference table G2110 lists 2892 twenty-one-bit patterns covering the addresses 0 through 2819 and beginning with “0” and ending with “1”. The 2892 patterns are as follows:

691 patterns produced by inverting all bits of F2, omitting one head bit, and adding “0011”

432 patterns produced by omitting one head bit of D and then adding “0011”

708 patterns produced by inverting all bits of F3, then omitting two head bits, and then adding “00011”

442 patterns produced by inverting all bits of F4, then omitting three head bits, and then adding “000011”

274 patterns produced by inverting all bits of F5, then omitting four head bits, and then adding “0000011”

170 patterns produced by inverting all bits of F6, then omitting five head bits, and then adding “00000011”

107 patterns produced by inverting all bits of F7, then omitting six head bits, and then adding “000000011”

68 patterns produced by inverting all bits of F8, then omitting seven head bits, and then adding “0000000011”

twenty-one bit patterns produced by further adding “1” to the tails of the above twenty-bit patterns

A reference table G2000 lists 1765 twenty-bit patterns covering the addresses 0 through 1764 and beginning and ending with “0”. The 1765 patterns are as follows:

668 patterns produced by omitting two head bits of E2 and then adding “0011”

432 patterns produced by omitting three head bits of E3 and then adding “00011”

276 patterns produced by omitting four head bits of E4 and then adding “000011”

174 patterns produced by omitting five head bits of E5 and then adding “0000011”

108 patterns produced by omitting six head bits of E6 and then adding “00000011”

66 patterns produced by omitting seven had bits of E7 and then adding “000000011”

41 patterns produced by omitting eight head bits of E8 and then adding “0000000011”

twenty-bit patterns produced by further adding “0” to the above nineteen-bit patterns

A reference table G2010 lists 1812 twenty-bit patterns covering the addresses 0 through 1811 and beginning with “0” and ending with “1”. The 1812 patterns are as follows:

708 patterns produced by inverting all bits of F3, then omitting two head bits, and then adding “0011”

422 patterns produced by inverting all bits of F4, then omitting three head bits, and then adding “00011”

274 patterns produced by inverting all bits of F5, then omitting four head bits, and then adding “000011”

170 patterns produced by inverting all bits of F6, then omitting five head bits, and then adding “0000011”

107 patterns produced by inverting all bits of F7, then omitting six head bits, and then adding “00000011”

68 patterns produced by inverting all bits of F8, then omitting seven head bits, and then adding “000000011”

43 patterns produced by inverting all bits of F9, then omitting eight head bits, and then adding “0000000011”

twenty-bit patterns produced by further adding “1” to the tails of the above nineteenth-bit patterns

A reference table G1900 lists 1123 nineteen-bit patterns covering the addresses 0 through 1122 and beginning and ending with “0”. The 1123 patterns are as follows:

432 patterns produced by omitting 3 head bits of E3 and then adding “0011”

276 patterns produced by omitting 4 head bits of E4 and then adding “00011”

174 patterns produced by omitting 5 head bits of E5 and then adding “000011”

108 patterns produced by omitting 6 head bits of E6 and then adding “0000011”

66 patterns produced by omitting 7 head bits of E7 and then adding “00000011”

41 patterns produced by omitting 8 head bits of E8 and then adding “000000011”

26 patterns produced by omitting 9 head bits of E9 and then adding “0000000011”

19-bit patterns produced by further adding “0” to the above 18-bit patterns

A reference table G1910 lists 1130 patterns covering the addresses 0 through 1129 and beginning with “0” and ending with “1”. The 1130 patterns are as follows:

442 patterns produced by inverting all bits of F4, then omitting 3 head bits, and then adding “0011”

274 patterns produced by inverting all bits of F5, then omitting 4 head bits, and then adding “00011”

170 patterns produced by inverting all bits of F6, then omitting 5 head bits, and then adding “000011”

107 patterns produced by inverting all bits of F7, then omitting 6 head bits, and then adding “0000011”

68 patterns produced by inverting all bits of F8, then omitting 7 head bits, and then adding “00000011”

43 patterns produced by inverting all bits of F9, then omitting 8 head bits, and then adding “000000011”

26 patterns produced by inverting all bits of FA, then omitting 9 head bits, and then adding “0000000011”

19-bit patterns produced by further adding “1” to the tails of the above 19-bit patterns

A reference table G1800 lists 708 eighteen-bit patterns covering the addresses 0 through 707 and beginning and ending with “0”. The 708 patterns are as follows:

276 patterns produced by omitting 4 head bits of E4 and then adding “0011”

174 patterns produced by omitting 5 head bits of E5 and then adding “00011”

108 patterns produced by omitting 6 head bits and then adding “000011”

66 patterns produced by omitting 7 head bits of E7 and then adding “0000011”

41 patterns produced by omitting 8 head bits of E8 and then adding “00000011”

26 patterns produced by omitting 9 head bits of E9 and then adding “000000011”

17 patterns produced by omitting 10 head bits of EA and then adding “0000000011”

18-bit patterns produced by further adding “0” to the tails of the above 17-bit patterns

A reference table G1810 lists 704 eighteen-bit patterns covering the addresses 0 through 703 and beginning with “0” and ending with “1”. The 704 patterns are as follows:

274 patterns produced by inverting all bits of F5, then omitting 4 head bits, and then adding “0011”

170 patterns produced by inverting all bits of F6, then omitting 5 head bits, and then adding “00011”

107 patterns produced by inverting all bits of F7, then omitting 6 head bits, and then adding “000011”

68 patterns produced by inverting all bits of F8, then omitting 7 head bits, and then adding “0000011”

43 patterns produced by inverting all bits of F9, then omitting 8 head bits, and then adding “00000011”

26 patterns produced by inverting all bits of FA, then omitting 9 head bits, and then adding “000000011”

16 patterns produced by inverting all bits of FB, then omitting 10 head bits, and then adding “0000000011”

19-bit patterns produced by further adding “1” to the tails of the above 17-bit patterns

A reference table G1700 lists 442 seventeen-bit patterns covering the addresses 0 through 441 and beginning and ending with “0”. The 442 patterns are as follows:

174 patterns produced by inverting all bits of E5, then omitting 5 head bits, and then adding “0011”

108 patterns produced by inverting all bits of E6, then omitting 6 head bits, and then adding “00011”

66 patterns produced by inverting all bits of E7, then omitting 7 head bits, and then adding “000011”

41 patterns produced by inverting all bits of E8, then omitting 8 head bits, and then adding “0000011”

26 patterns produced by inverting all bits of E9, then omitting 9 head bits, and then adding “00000011”

6 17 patterns produced by inverting all bits of EA, then omitting 10 head bits, and then adding “000000011”

10 patterns produced by inverting all bits of EB, then omitting 11 head bits, and then adding “0000000011”

17-bit patterns produced by further adding “1” to the tails of the above 16-bit patterns

A reference table G1710 lists 440 seventeen-bit patterns covering the addresses 0 through 439 and beginning with “0” and ending with “1”. The 440 patterns are as follows:

170 patterns produced by inverting all bits of F6, then omitting 5 head bits, and then adding “0011”

107 patterns produced by inverting all bits of F7, then omitting 6 head bits, and then adding “00011”

68 patterns produced by inverting all bits of F8, then omitting 7 head bits, and then adding “000011”

43 patterns produced by inverting all bits of F9, then omitting 8 head bits, and then adding “0000011”

26 patterns produced by inverting all bits of FA, then omitting 9 head bits, and then adding “00000011”

16 patterns produced by inverting all bits of FB, then omitting 10 head bits, and then adding “000000011”

10 patterns produced by inverting all bits of FC, then omitting 11 head bits, and then adding “0000000011”

17-bit patterns produced by further adding “1” to the tails of the above 16-bit patterns

A reference table G1600 lists 274 sixteen-bit patterns covering the addresses 0 through 273 and beginning and ending with “0”. The 274 patterns are as follows:

108 patterns produced by omitting 6 head bits of E6, and then adding “0011”

66 patterns produced by omitting 7 head bits of E7, and then adding “00011”

41 patterns produced by omitting 8 head bits of E8, and then adding “000011”

26 patterns produced by omitting 9 head bits of E9, and then adding “0000011”

17 patterns produced by omitting 10 head bits of EA, and then adding “00000011”

10 patterns produced by omitting 11 head bits of EB, and then adding “000000011”

6 patterns produced by omitting 12 head bits of EC, and then adding “0000000011”

16-bit patterns produced by further adding “0” to the tails of the above 15-bit patterns

A reference table G1610 lists 277 sixteen-bit patterns covering the addresses 0 through 276 and beginning with “0” and ending with “1”. The 277 patterns are as follows:

107 patterns produced by inverting all bits of F7, then omitting 6 head bits, and then adding “0011”

68 patterns produced by inverting all bits of F8, then omitting 7 head bits, and then adding “00011”

43 patterns produced by inverting all bits of F9, then omitting 8 head bits, and then adding “000011”

26 patterns produced by inverting all bits of FA, then omitting 9 head bits, and then adding “0000011”

16 patterns produced by inverting all bits of FB, then omitting 10 head bits, and then adding “00000011”

10 patterns produced by inverting all bits of FC, then omitting 11 head bits, and then adding “000000011”

7 patterns produced by inverting all bits of FD, then omitting 12 head bits, and then adding “0000000011”

16-bit patterns produced by further adding “1” to the tails of the above 15-bit patterns

A reference table G1500 lists 170 fifteen-bit patterns covering the addresses 0 through 169 and beginning and ending with “0”. The 170 patterns are as follows:

66 patterns produced by omitting 7 head bits of E7, and then adding “0011”

41 patterns produced by omitting 8 head bits of E8, and then adding “00011”

26 patterns produced by omitting 9 head bits of E9, and then adding “000011”

17 patterns produced by omitting 10 head bits of EA, and then adding “0000011”

10 patterns produced by omitting 11 head bits of EB, and then adding “00000011”

6 patterns produced by omitting 12 head bits of EC, and then adding “000000011”

4 patterns produced by omitting 13 head bits of ED, and then adding “0000000011”

15-bit patterns produced by further adding “0” to the tails of the above 14-bit patterns

A reference table G1510 lists 174 fifteen-bit patterns covering the addresses 0 through 173 and beginning with “0” and ending with “1”. The 174 patterns are as follows:

68 patterns produced by inverting all bits of F8, then omitting 7 head bits, and then adding “0011”

43 patterns produced by inverting all bits of F9, then omitting 7 head bits, and then adding “00011”

26 patterns produced by inverting all bits of FA, then omitting 9 head bits, and then adding “000011”

16 patterns produced by inverting all bits of FB, then omitting 10 head bits, and then adding “0000011”

10 patterns produced by inverting all bits of FC, then omitting 11 head bits, and then adding “00000011”

7 patterns produced by inverting all bits of FD, then omitting 12 head bits, and then adding “000000011”

4 patterns produced by inverting all bits of FE, then omitting 13 head bits, and then adding “0000000011”

15-bit patterns produced by further adding “1” to the tails of the above 14-bit patterns

A reference table G1400 lists 107 fourteen-bit patterns covering the addresses 0 through 106 and beginning and ending with “0”. The 170 patterns are as follows:

41 patterns produced by omitting 8 head bits of E8, and then adding “0011”

26 patterns produced by omitting 9 head bits of E9, and then adding “00011”

17 patterns produced by omitting 10 head bits of EA, and then adding “000011”

10 patterns produced-by omitting 11 head bits of EB, and then adding “0000011”

6 patterns produced by omitting 12 head bits of EC, and then adding “00000011”

4 patterns produced by omitting 13 head bits of ED, and then adding “000000011”

3 patterns produced by omitting 14 head bits of EE, and then adding “0000000011”

14-bit patterns produced by further adding “0” to the tails of the above 13-bit patterns

A reference table G1410 lists 108 fourteen-bit patterns covering the addresses 0 through 107 and beginning with “0” and ending with “1”. The 108 patterns are as follows:

43 patterns produced by inverting all bits of F9, then omitting 8 head bits, and then adding “0011”

26 patterns produced by inverting all bits of FA, then omitting 9 head bits, and then adding “00011”

16 patterns produced by inverting all bits of FB, then omitting 10 head bits, and then adding “000011”

10 patterns produced by inverting all bits of FC, then omitting 11 head bits, and then adding “0000011”

7 patterns produced by inverting all bits of FD, then omitting 12 head bits, and then adding “00000011”

4 patterns produced by inverting all bits of FE, then omitting 13 head bits, and then adding “000000011”

2 patterns produced by inverting all bits of FF, then omitting 14 head bits, and then adding “0000000011”

14-bit patterns produced by further adding “1” to the tails of the above 13-bit patterns

A reference table G1300 lists 68 thirteen-bit patterns covering the addresses 0 through 67 and beginning and ending with “0”. The 170 patterns are as follows:

26 patterns produced by omitting 9 head bits of E9, and then adding “0011”

17 patterns produced by omitting 10 head bits of FA, and then adding “00011”

10 patterns produced by omitting 11 head bits of EB, and then adding “000011”

6 patterns produced by omitting 12 head bits of EC, and then adding “0000011”

4 patterns produced by omitting 13 head bits of ED, and then adding “00000011”

3 patterns produced by omitting 14 head bits of EE, and then adding “000000011”

2 patterns produced by omitting 15 head bits of EF, and then adding “0000000011”

13-bit patterns produced by further adding “0” to the tails of the above 12-bit patterns

A reference table G1310 lists 66 thirteen-bit patterns covering the addresses 0 through 65 and beginning with “0” and ending with “1”. The 66 patterns are as follows:

26 patterns produced by inverting all bits of FA, then omitting 9 head bits, and then adding “0011”

16 patterns produced by inverting all bits of FB, then omitting 10 head bits, and then adding “00011”

10 patterns produced by inverting all bits of FC, then omitting 11 head bits, and then adding “000011”

7 patterns produced by inverting all bits of FD, then omitting 12 head bits, and then adding “0000011”

4 patterns produced by inverting all bits of FE, then omitting 13 head bits, and then adding “00000011”

2 patterns produced by inverting all bits of FF, then omitting 14 head bits, and then adding “000000011”

1 pattern produced by inverting all bits of FG, then omitting 15 head bits, and then adding “0000000011”

13-bit patterns produced by further adding “1” to the tails of the above 12-bit patterns

A reference table G1200 lists 43 twelve-bit patterns covering the addresses 0 through 42 and beginning and ending with “0”. The 43 patterns are as follows:

17 patterns produced by omitting 10 head bits of EA, and then adding “0011”

10 patterns produced by omitting 11 head bits of EB, and then adding “00011”

6 patterns produced by omitting 12 head bits of EC, and then adding “000011”

4 patterns produced by omitting 13 head bits of ED, and then adding “0000011”

3 patterns produced by omitting 14 head bits of EE, and then adding “00000011”

2 patterns produced by omitting 15 head bits of EF, and then adding “000000011”

1 pattern produced by omitting 16 head bits of EG, and then adding “0000000011”

12-bit patterns produced by further adding “0” to the tails of the above 11-bit patterns

A reference table G1210 lists 41 twelve-bit patterns covering the addresses 0 through 40 and beginning with “0” and ending with “1”. The 41 patterns are as follows:

16 patterns produced by inverting all bits of FB, then omitting 10 head bits, and then adding “0011”

10 patterns produced by inverting all bits of FC, then omitting 11 head bits, and then adding “00011”

7 patterns produced by inverting all bits of FD, then omitting 12 head bits, and then adding “000011”

4 patterns produced by inverting all bits of FE, then omitting 13 head bits, and then adding “0000011”

2 patterns produced by inverting all bits of FF, then omitting 14 head bits, and then adding “00000011”

1 pattern produced by inverting all bits of FG, then omitting 14 head bits, and then adding “000000011”

1 pattern produced by inverting all bits of FG, then omitting 16 head bits, and then adding “0000000011”

12-bit patterns produced by further adding “1” to the tails of the above 11-bit patterns

A reference table G1100 lists 26 eleven-bit patterns covering the addresses 0 through 25 and beginning and ending with “0”. The 43 patterns are as follows:

10 patterns produced by omitting 11 head bits of EB, and then adding “0011”

6 patterns produced by omitting 12 head bits of EC, and then adding “00011”

4 patterns produced by omitting 13 head bits of ED, and then adding “000011”

3 patterns produced by omitting 14 head bits of EE, and then adding “0000011”

2 patterns produced by omitting 15 head bits of EF, and then adding “00000011”

1 pattern produced by omitting 16 head bits of EG, and then adding “000000011”

11-bit patterns produced by further adding “0” to the tails of the above 10-bit patterns

A reference table G1110 lists 26 eleven-bit patterns covering the addresses 0 through 25 and beginning with “0” and ending with “1”. The 41 patterns are as follows:

10 patterns produced by inverting all bits of FC, then omitting 11 head bits, and then adding “0011”

7 patterns produced by inverting all bits of FD, then omitting 12 head bits, and then adding “00011”

4 patterns produced by inverting all bits of FE, then omitting 13 head bits, and then adding “000011”

2 patterns produced by inverting all bits of FF, then omitting 14 head bits, and then adding “0000011”

1 pattern produced by inverting all bits of FG, then omitting 15 head bits, and then adding “00000011”

1 pattern produced by inverting all bits of FG, then omitting 14 head bits, and then adding “000000011”

1 pattern produced by inverting all bits of FG, then omitting 17 head bits (all bits), and then adding “0000000011”, i.e., pattern “00000000

11-bit patterns produced by further adding “1” to the tails of the above 10-bit patterns

A reference table G1000 lists 17 ten-bit patterns covering the addresses 0 through 15 and beginning and ending with “0”. The 17 patterns are as follows:

6 patterns produced by omitting 12 head bits of EC, and then adding “0011”

4 patterns produced by omitting 13 head bits of ED, and then adding “00011”

3 patterns produced by omitting 14 head bits of EE, and then adding “000011”

2 patterns produced by omitting 15 head bits of EF, and then adding “0000011”

1 pattern produced by omitting 16 head bits of EG, and then adding “00000011”

10-bit patterns produced by further adding “0” to the tails of the above 19-bit patterns

A reference table G1010 lists 17 ten-bit patterns covering the addresses 0 through 16 and beginning with “0” and ending with “1”. The 17 patterns are as follows:

7 patterns produced by inverting all bits of FD, then omitting 12 head bits, and then adding “0011”

4 patterns produced by inverting all bits of FE, then omitting 13 head bits, and then adding “00011”

2 patterns produced by inverting all bits of FF, then omitting 14 head bits, and then adding “000011”

1 pattern produced by inverting all bits of FG, then omitting 15 head bits, and then adding “0000011”

1 pattern produced by inverting all bits of FG, then omitting 16 head bits, and then adding “00000011”

1 pattern produced by inverting all bits of FG, then omitting 17 head bits (all bits), and then adding “000000011”, i.e., pattern “000000011”

1 pattern produced by inverting all bits of FG, then omitting 17 head bits (all bits), and then adding “000000001”, i.e., pattern “000000001”

10-bit patterns produced by further adding “1” to the tails of the above 9-bit patterns

The conversion tables will be described with reference to FIGS. 31 through 38. As shown, the conversion tables correspond to conversion tables H000 through K011 shown in FIGS. 4 and 5. Specifically, in the 16-to-24 conversion table shown in FIGS. 4 and 5, 2¹⁶ data bits are divided into thirty-six kinds of conversion table groups belonging to the ranges L1 through L16.

In each of the conversion tables shown in FIGS. 31 through 38, a particular “head bit+reference table+tail bit”, a particular reference table address (RADR), a particular reference table (RTBL), a particular number of head bits and a particular number of tail bits are listed in each of the ranges, which are the subdivisions of the input data.

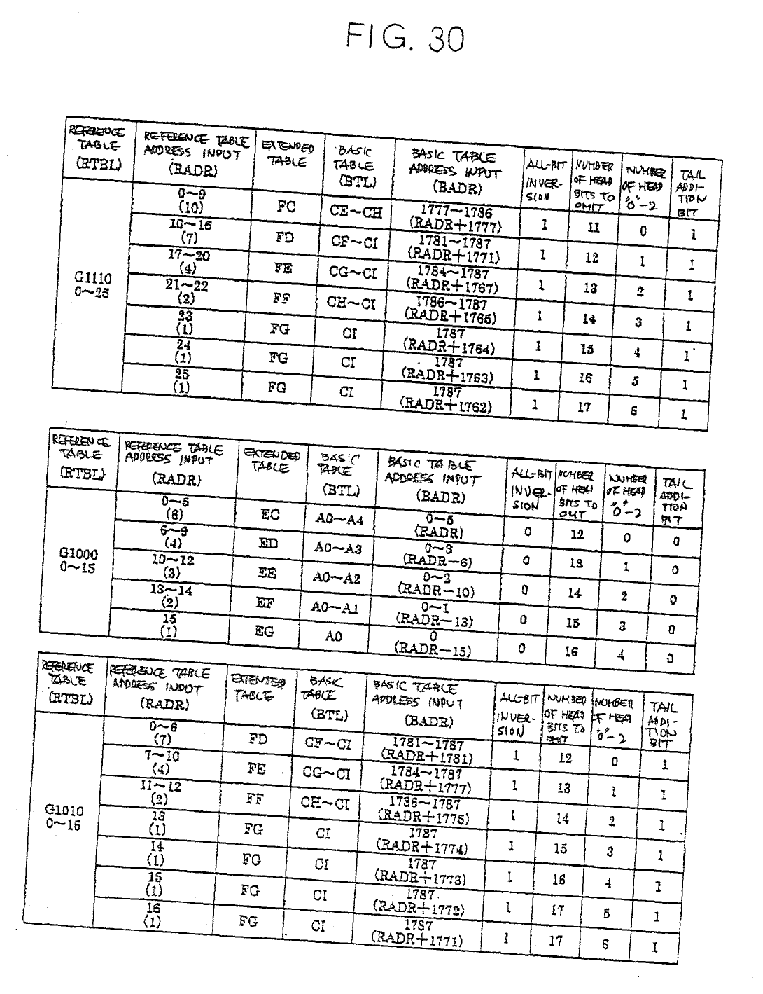

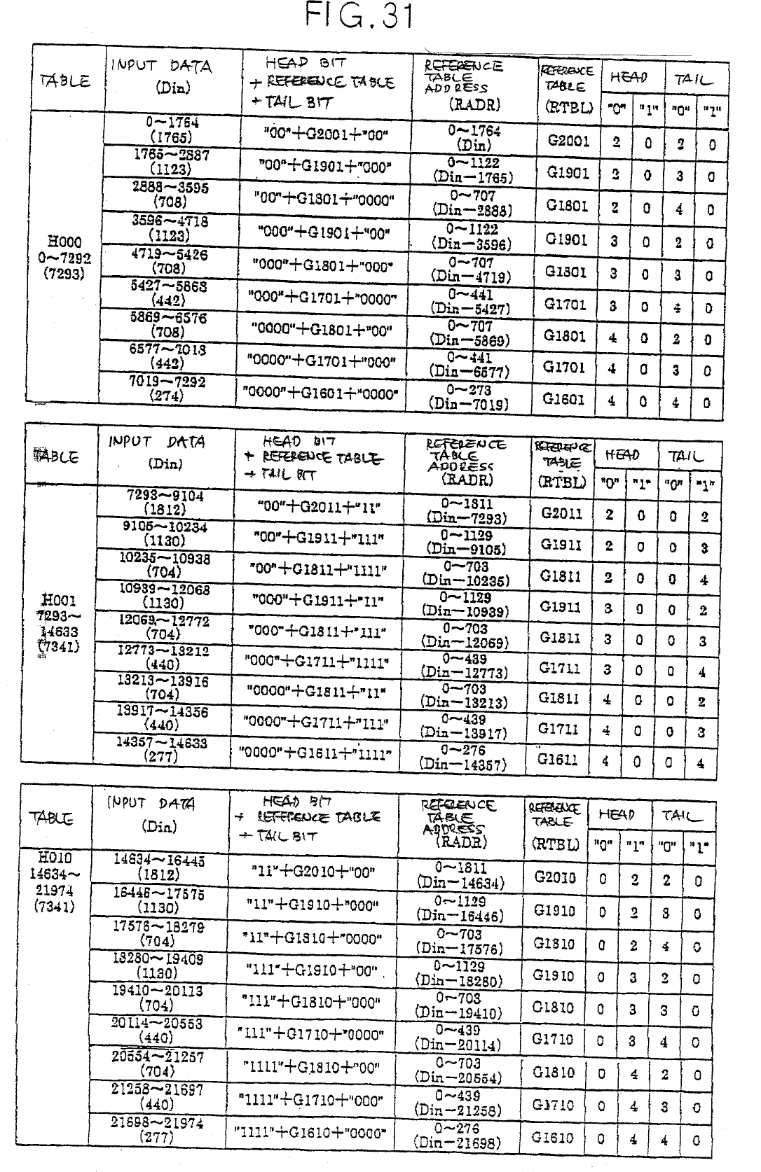

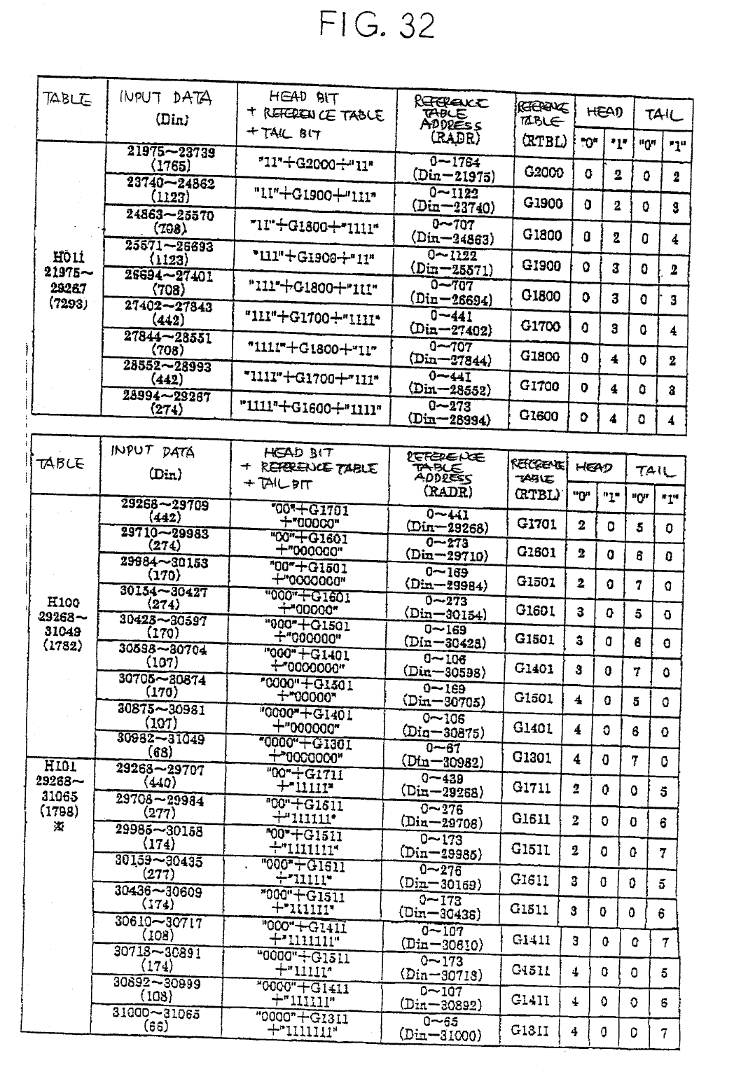

The first column shows the tables (groups) H000 through K011 together with Din numbers corresponding to the 65536 patterns of the sixteen-bit input data. For example, “0-7292 (7293)” shown below the conversion table “H000”, FIG. 30, indicates the range “0-7292” and total number “7293” of the input data Din when the table H000 is selected. However, the conversion tables H100 and H101 shown in FIG. 32 include 1782 patterns and 1798 patterns; that is, the total numbers are different despite that the tables H100 and H101 both are selected. In such a case, the smaller total number “1782” is the total number common to the tables H100 and H101. Therefore, 1782 patterns are selected out of the table H101 greater in total number than the table H100, leaving the remaining sixteen patterns unused.

To select 1782 patterns out of 1,798 patterns, they may be mechanically selected from the head of the basic tables, as will be described specifically later. Alternatively, patterns with a small number of times of inversion or with a small or a great DC component may be selected, as desired. Asterisk is attached to the total numbers of patterns including such unused patterns.

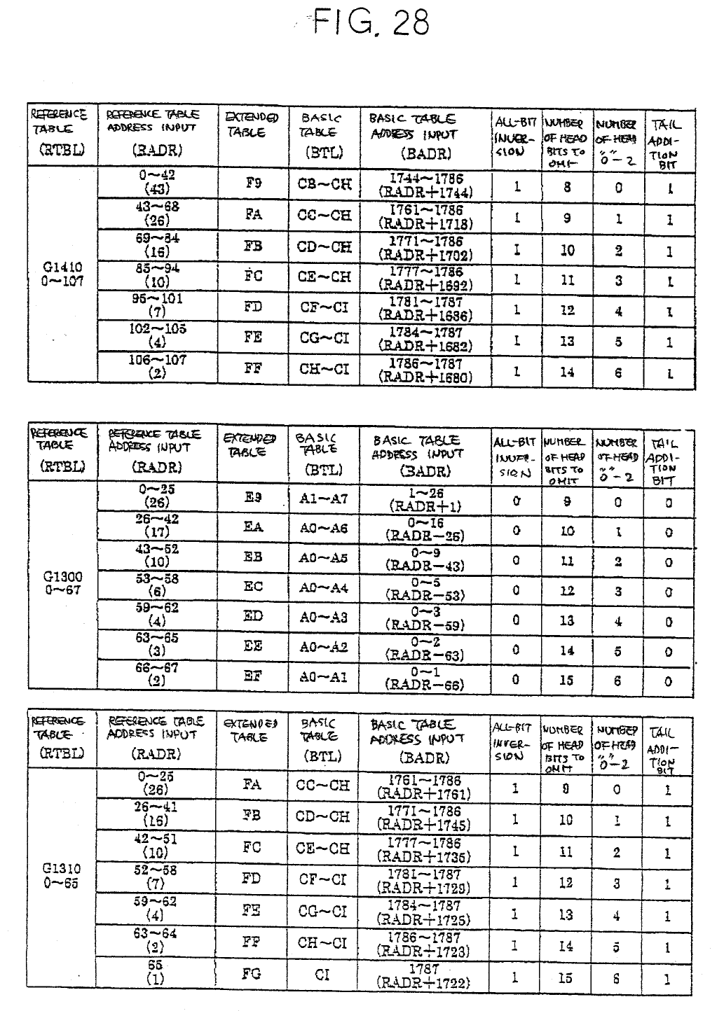

FIG. 28 shows conversion tables K000, K001, K010 and K011 show Din numbers up to “66535” and “66974” exceeding 65536 patterns. However, the range actually used is up to “65535”.

The second column shows input data (Din) corresponding to the reference tables. In the conversion table H000, for example, the following nine ranges and total numbers corresponding to the input data 0 through 7292 (7293 patterns in total) are shown:

0-1764 (1765 patterns)

1765-2887 (1123 patterns)

2888-3595 (708 patterns)

3596-4718 (1123 patterns)

4719-5426 (708 patterns)

5427-5868 (442 patterns)

5869-6576 (708 patterns)

6577-7018 (422 patterns)

7019-7292 (274 patterns)

The first row, for example, shows a Din range 0-1764 and total number 1765 corresponding to the reference table G2001.

The third column shows “head bit+reference table+tail bit”. The head bit is representative of continuous bits shown in the sixth and seventh columns. Likewise, the tail bit is representative of continuous bits shown in the eighth and ninth columns. The reference table (RTBL) indicates a reference table shown in the fifth column. For example, “00”+G2001+“00” in the conversion table H000 shows that two head bits of twenty-four channel bits are “00”, that twenty bits following the head bits are channel bits listed in the reference table G2001, and that two tail bits are “00”.

The fourth column shows a reference table address (RADR). For example, input data (Din) 0-1764 in the conversion table H000 indicates a relation between the reference table address (RADR) and the input data (Din) when the reference table G2001, i.e., G2000 in practice is selected. In this case, RADR=Din holds. As for the next input data (Din) 1765-2887, a reference table address (RADR) 0-1122 has a relation of RADA=Din−1765.

The fifth column shows a reference table (RTBL). As for a reference table G2001, the first three letters “G200” are representative of the reference table G2000 with “0” added to the tail. Also, the last letter “1” shows that all the channel bits derived from the reference table G2000 will be inverted by the last processing. Likewise, as for a reference table G2011, the first three letters “G201” are representative of a reference table G2010 with “0” added to the tail; the last letter “1” shows that all the channel bits derived from the reference table G2010 will be inverted by the last processing. The last letter “0” shows that such all-bit inversion will not be executed. In this manner, in the reference table G2001, the reference table G2000 actually used is represented by five bits while an all-bit inversion flag is represented by one bit.

The sixth to ninth columns show the numbers of bits of “0” and “1” at the head and those of “0” and “1” at the tail.

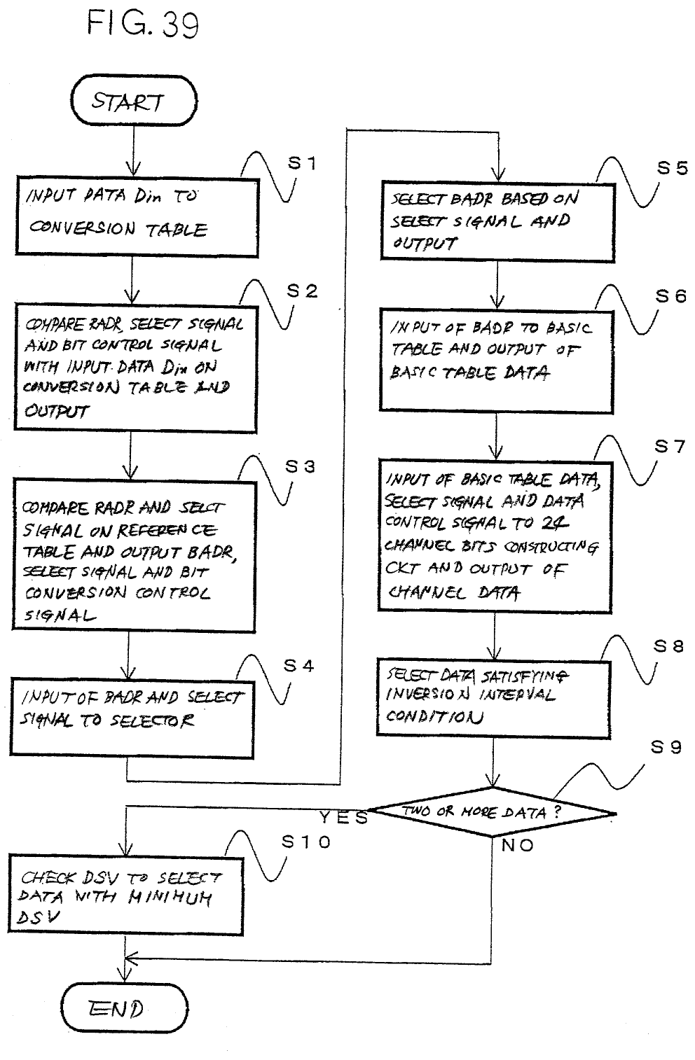

Referring to FIGS. 2 and 39, major part of a coding procedure unique to the illustrative embodiment will be described in detail. As shown, the conversion table processing section 11 receives sixteen-bit input data Din 20 (step S1). The processing section 11 selects one of the group of conversion tables H000, H001, H010, H011, H100 and H101, the group of conversion tables H110 and H111, the group of conversion tables H200 and H211, the group of conversion tables H201 and H210, the group of conversion tables H300, H301, H310 and H311, the group of conversion tables I000 and I010, the group of conversion tables I001 and I0101, the group of conversion tables I100, I101, I110 and I111, the group of conversion tables J000 and J001, the group of conversion tables J010 and J011, the group of conversion tables J100, J101, J110 and J111, and the conversion tables K000, K001, K010 and K011 designated by the range numbers Li.

The processing section 11 then delivers a reference table address (RADR) 21 and a reference table information signal 22 to the reference table processing section 12. At the same time, the processing section 11 delivers a bit addition control signal 23 to the twenty-four channel bits constructing circuit 15 (step S2).

The reference table processing section 12 determines a reference table and the number of tables to select in accordance with the reference table address (RADR) 21 and reference table information signal 22. The processing section 12 delivers to the selector 13 up to four groups of thirteen-bit basic table addresses (BADR) 24 searched for on the reference table. At the same time, the processing section 12 delivers a select signal to the selector 13 and twenty-four channel bit constructing circuit 15. Further, the processing section 12 delivers a bit conversion control signal 26 to the twenty-four channel bits constructing circuit 15 (step S3).

The selector 13 receives the up to four groups of thirteen-bit basic table addresses (BARD) 24 and select signal 25 (step S4). In response, the selector 13 selects the thirteen-bit address (BADR) 27 of the four groups clock by clock in accordance with the select signal 25 while feeding it to the basic table processing section 14.

The basic table processing section 14 selects seventeen-bit basic table output data 28 out of the basic table in accordance with the thirteen-bit addresses (BADR) 27 and delivers them to the twenty-four channel bits constructing circuit 15 (step S6).

The twenty-four channel bits constructing circuit 15 executes bit inversion, bit addition or bit omission with the basic table output data 28 in accordance with the select signal 25, bit conversion control signal 26 and bit addition control signal 23. The circuit 15 then outputs twenty-four channel bits as output data (Dout) 29 (step S7). Subsequently, the circuit 15 examines the minimum inversion interval and maximum inversion interval of the channel data derived from one or more tables, which are selected in accordance with the select signal 25, thereby selecting only the table or tables satisfying the above conditions (step S8). Channel data not satisfying the conditions cannot be selected. More specifically, when the minimum inversion interval is “2”, two or more identical bits should continuously appear inclusive of the boundary between twenty-four bits and twenty-four bits. Also, when the maximum inversion interval is “8”, eight identical bits or less should continuously appear inclusive of a boundary between twenty-four bits and twenty-four bits.

Assume that a plurality of twenty-four channel bit data satisfy the minimum inversion interval and maximum inversion interval stated above (YES, step S9). Then, a single channel bit whose DSV is smaller by one in absolute value is selected for a DC-free configuration (step S10). More specifically, the DSV of the twenty-four channel bit data and that of the last DSV are added to produce a sum DSV. A table whose sum DSV in absolute value is closer to zero is finally selected. Alternatively, there may be selected a channel bit whose DSV in absolute value decreases at a position P bits ahead (P>1).

Assume that the answer of the step S9 is NO, and that a single group of twenty-four channel bit data is selected. Then, the above data is selected without comparison based on DSV being executed.

The signals input and output from the function blocks shown in FIG. 2 will be described more specifically with reference to the other figures as well.

Assume that a single conversion table, e.g., H000 is selected out of a single group in the step S2. Then, a single reference table address (RADR) 21 is output while the other three addresses all are “0”. The reference table information signal is “0”. When two conversion tables, e.g., H100 and H101 are selected, two reference table addresses (RADR) 21 are output while the other two addresses both are “0”; the reference table information signal is “1”. Further, when four conversion tables, e.g., H300, H301, H310 and H311 are selected, four reference table addresses (RADR) 21 are output; the reference table information signal is “3”. This is why four groups of reference table addresses (RADR) 21 having thirteen bits each are shown.

The reference table information signal is a twenty-two-bit control signal. Twenty bits of this signal consist of four groups of five bits each designating a single reference table. The remaining two bits of the above signal allow up to four tables to be selected. The bit addition control signal 23 is a fifty-two-bit control signal. This signal consists of four bits each being assigned to one of four reference table groups and representative of an all-bit inversion flag, and forty-eight bits made up of four groups of twelve bits each being representative of “0”/“1” of the head bit or that of the tail bit of the individual reference table group.

If a single reference table is selected in the step S3, then a single basic table address (BADR) 24 is output. The other three reference table addresses (BADR) all are “0”. The select signal 25 is “0”.

When two reference tables are used, two basic table addresses (BADRs) 24 are output. The other two basic table addresses (BADR)s both are “0”. As for the select signal 25, a single symbol conversion period is halved in order to output “0” during the former half and output “1” during the latter half. Consequently, the selector 13 and twenty-four channel bits constructing circuit 15 perform time-division operation corresponding to two basic tables with a single basic table.

When four reference tables all are used at the same time, four basic table addresses (BADRs) 24 are output. As for the select signal 25, a single conversion period is quadrisected in order to output “0” during the first one-quarter, output “1” during the second one-quarter, output “2” during the third one-quarter, and output “3” during the fourth one-quarter. This implements time-division operation corresponding to four basic tables with a single basic table.

As stated above, four basic table addresses (BADR) 24 have thirteen bits each while the select signal 25 has two bits. Further, the bit conversion control signal 26 is a forty-bit control signal consisting of four groups of ten bits each being assigned to one of four groups and made up of one all-bit inversion bit, five bits representative of the number of head bits to be omitted, three bits representative of “number of head “0”−2”, and one tail addition bit.

In the step S7, the twenty-four channel bits constructing circuit 15 executes, based on the all-bit inversion bit included in the bit conversion control signal 26, inversion or non-inversion with table data or basic table data 28 input in accordance with the four groups “0” through “3” of the select signal 25. Also, the circuit 15 omits the head bits in accordance with the designated number of head bits to be omitted. Further, if “number of “0” head−2” is n, then the circuit 15 adds “n “0” bits+0011” to the head bit. In addition, the circuit 15 adds bits in accordance with the tail addition bit also included in the bit conversion control signal 26.

The above circuit 15 inverts all bits of the data undergone bit conversion control in accordance with the reference table all-bit inversion flag represented by one bit of the bit control signal 23. The circuit 15 then adds bits to the head and tail by using the number of head “0” bits, the number of head “1” bits, the number of tail “0” bits, and the number of tail “1” bits, thereby outputting twenty-four channel bit data.

If two or four kinds of tables can be selected on the basis of the four portions 0 through 3 of the select signal 25, then whether or not the individual twenty-four-bit channel bit data satisfies the minimum inversion interval and maximum inversion interval stated earlier is determined. Only if a plurality of groups of twenty-channel bit data satisfying the above conditions exist, a channel bit whose DSV is smaller in absolute value is selected for a DC-free configuration. More specifically, a table whose DSV, which is the sum of the previous DSV and the last DSV, is closer to “0” in absolute value is finally selected. The output data Dout is the data finally selected by the circuit 15 after the above procedure.

A first, more specific coding procedure will be described by using specific numerical values hereinafter. Assume that the input data (Din) 20 is “9F4FH” (36687), that the tail bits of the previous channel bits are “ * * * 01111”, a DSV up to the end of the last symbol is “+8”, and that the following data bits are “0010H”.

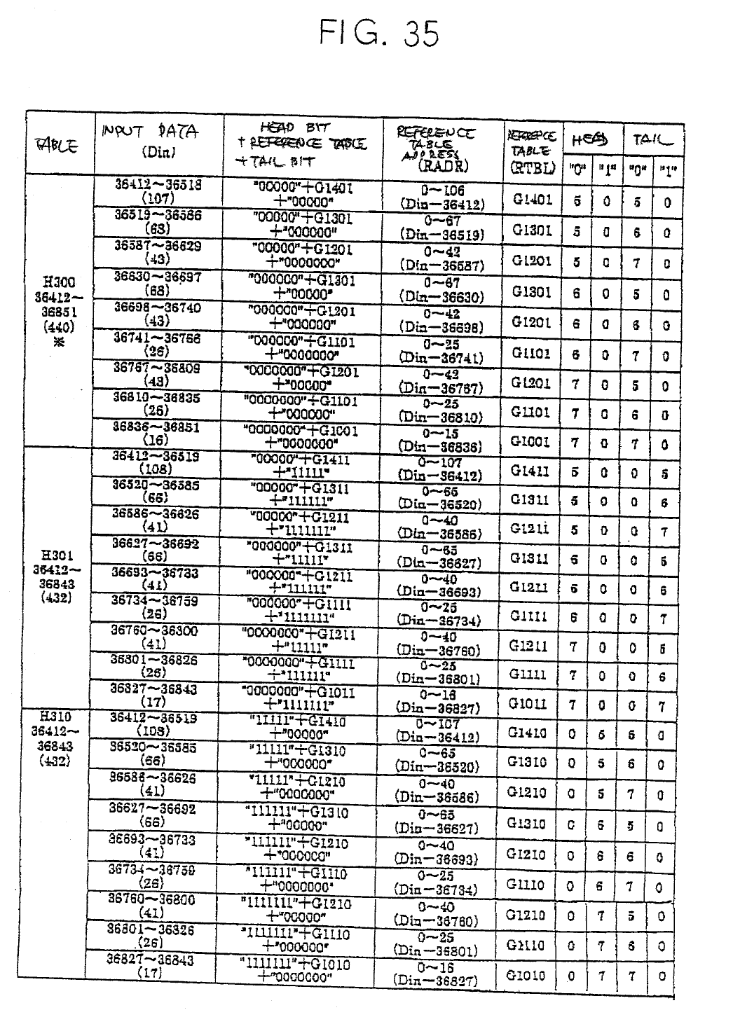

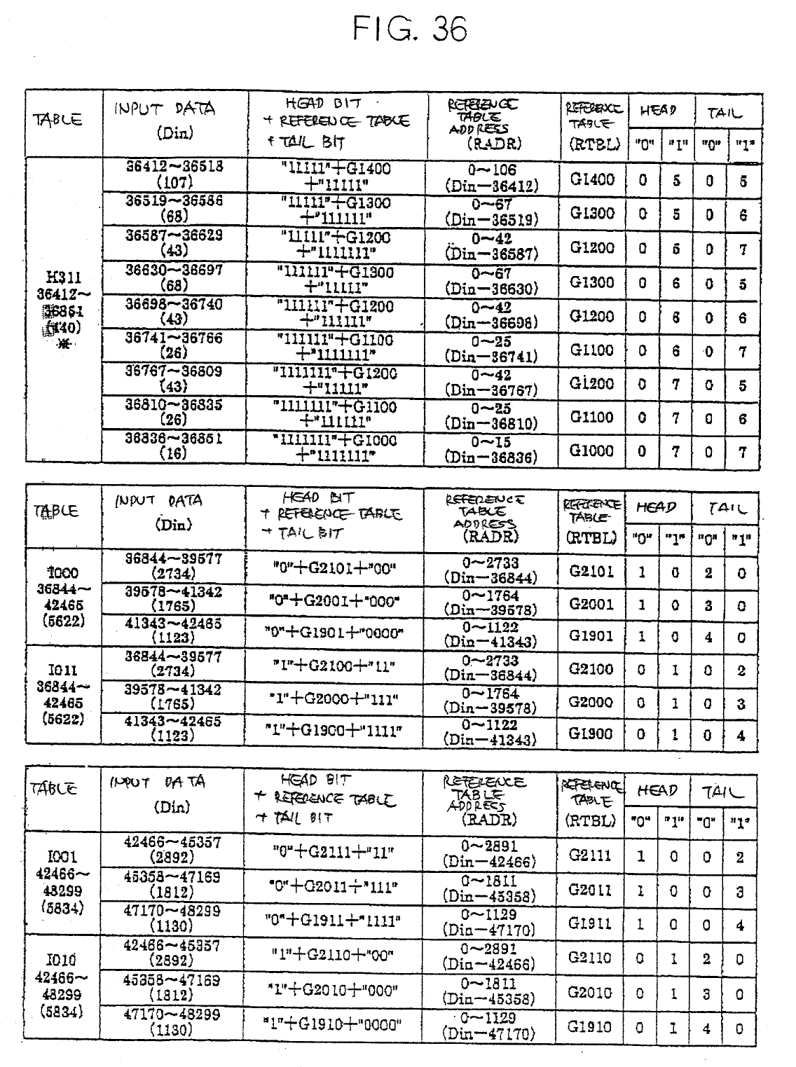

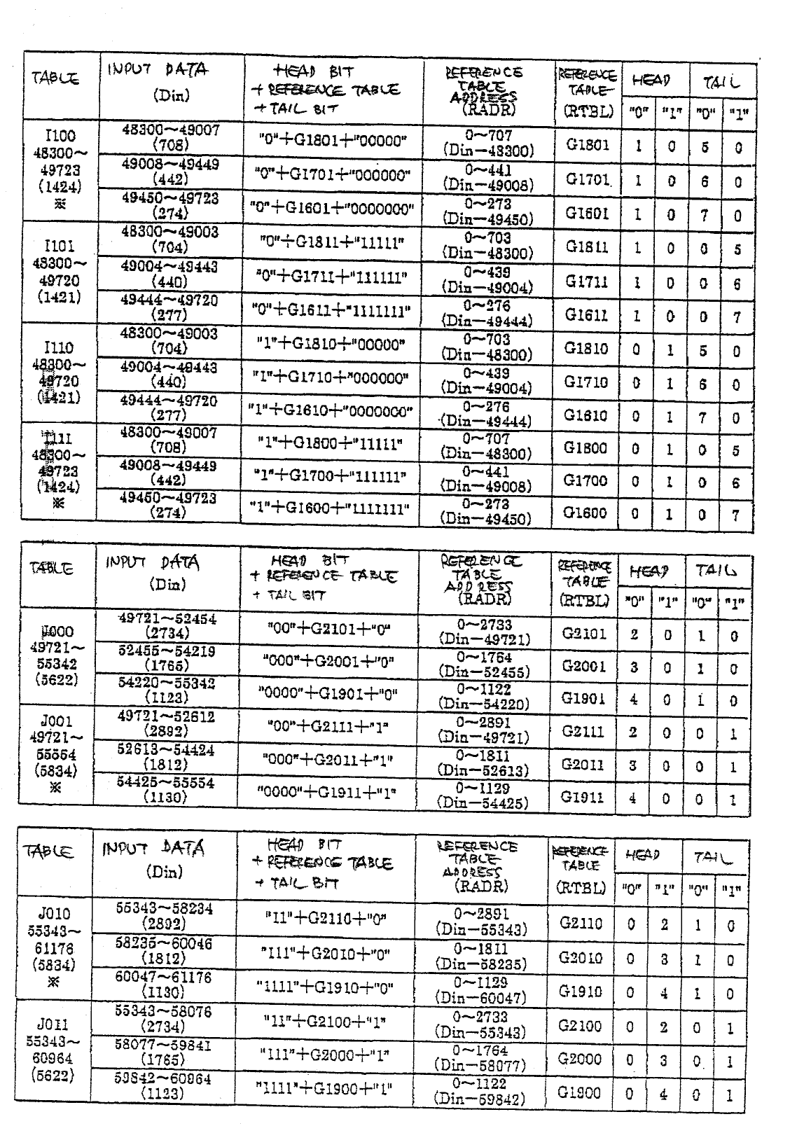

The conversion table processing section 11 selects reference tables. Specifically, in the conversion tables shown in FIGS. 31 through 38, the input data (Din) “36687” is contained in the tables H300, H301, H310 and H311 shown in FIGS. 35 and 36. The table H300 shows “000000”+G1301+“00000” and RADR=Din−36630=57. Therefore, a reference table (RTBL)=R1311, the number of continuous “0” head bits of “6” and the number of continuous “1” tail bits of “5” are selected.

Likewise, the table H301 shows “000000”+G1311+“11111” and RADR=Din−36627=60. Therefore, a reference table (RTBL)=R1311, the number of continuous “0” head bits of “6” and the number of continuous “1” tail bits of “5” are selected. Further, the table H310 shows “111111”+G1310+“00000” and RADR=Din−36627=60. Therefore, a reference table (RTBL)=R1310, the number of continuous “1” head bits of “6” and the number of continuous “0” tail bits of “5” are selected. In addition, the table H311 shows “111111”+G1300+“11111” and RADR=Din−36630=57. Therefore, a reference table (RTBL)=R1300, the number of continuous “1” head bits of “6” and the number of continuous “1” tail bits of “5” are selected.

The conversion table processing section 11 therefore feeds to the reference table processing section 12 four reference table addresses 21, i.e., RADR=57, 60, 60 and 57 and the reference table information signal 22, which designates the reference tables G1300, G1310, G1310 and G1300 with twenty bits and specifies the number of tables selected of “3” with two bits. Further, the processing section 11 feeds to the twenty-four channel bits constructing circuit 15 the bit control signal 23 made up of four all-bit inversion flag bits that are “1”, “1”, “0” and “0”, respectively, and forty-eight bits represented by “6050”, “6005”, “0650” and “0605”. These four forty-eight bits indicate the number of “0” head bits, the number of “1” head bits, the number of “0” tail bits, and the number of “1” tail bits.

The reference table processing section 12 selects extended tables and basic tables on the basis of the reference tables shown in FIGS. 22 through 30. Specifically, the processing section 12 receives the four table addresses 21 representative of two kinds of RADR=57 and 60 and the reference table information signal 22 representative of two kinds of reference tables G1300 and G1310. In the reference table (RTBL) G1300, FIG. 28, RADR=57 shows an extended table EC, basic tables A0 through A4, BARD=RADR−53=4, all-bit inversion of “0”, twelve head bits to be omitted, “number of head “0”−2” of “3”, and tail addition bit of “0”. In the other reference table (RTBL) G1310, FIG. 28, RADR=60 shows an extended table EF, basic tables CG through CI, BARD=RADR +1752=1785, all-bit inversion of “1”, thirteen head bits to be omitted, “number of head “0”−2” of “4”, and tail addition bit of “1”.

The reference table processing section 12 therefore outputs basic table addresses (BADR) of 4, 1785, 1785 and 4. The select signal 25 output from the processing section 12 varies in the order of “0”, “1”, “2” and “3” within a single clock while being input to the twenty-four channel bits constructing circuit 15. The bit conversion control signal 26 has four all-bit inversion bits that are “0”, “1”, “1” and “0”, twenty bits indicative of “12, “13”, “13” and “12” that are the numbers of head bits to be omitted, twelve bits indicative of “3”, “4”, “4” and “3” that are “numbers of head “0”−2”, and four tail addition bits that are “0”, “1”, “1” and “0”.

The selector 13 therefore sequentially delivers the basic table addresses of 4, 1785, 1785 and 4 to the basic table processing section 14 as the BADR 27 within a single clock.

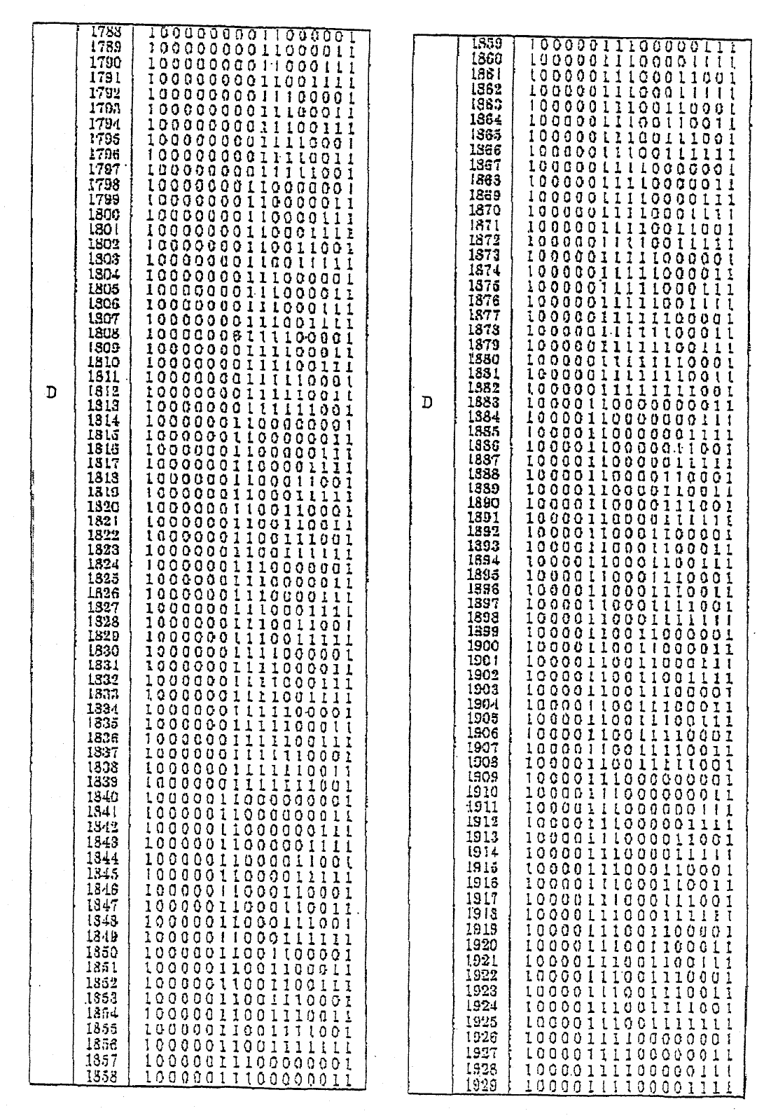

The basic table processing section 14 searches for the BADR of 4 on the basic table A4, FIG. 6, and searches for the BADR of 1785 on the basis table CG, FIG. 18, thereby producing seventeen-bit data. The processing section 14 then sequentially feeds the seventeen-bit data to the twenty-four channel bits constructing circuit 15 as the basic table output data 28 within a single clock. More specifically, the processing section 14 outputs the following four seventeen-bit data:

first data: “11111111111100110”

second data: “00000000000001100”

third data: “00000000000001100”

fourth data: “11111111111100110”

The twenty-four channel bits constructing circuit 15 produces four thirteen-bit data in accordance with the basic table data 28, select signal 25 and bit conversion control signal 26. Specifically, the circuit 15 omits twelve head bits of the above first data without effecting all-bit inversion and adds “0” to the tail of the same data, thereby producing first thirteen-bit data “0000011001100. The circuit 15 inverts all bits of the second seventeen-bit data, omits thirteen head bits, adds “000000” to the head, and adds “1” to the tail, thereby producing second thirteen-bit data “0000001100111”. In the same manner, the circuit 15 produces third thirteen-bit data “0000001100111” and fourth thirteen-bit data “0000011001100”.

Subsequently, the circuit 15 produces four twenty-four bit data from the above first to fourth thirteen-bit data and bit control signal 23. Specifically, the circuit 15 produces first twenty-four-bit data “000000111110011001100000” by taking account of the all-bit inversion flag of “1”, the number of head “0” bits of “6050”, the number of head “1” bits, the number of tail “0” bits, and the number of tail “1” bits. The circuit 15 produces second twenty-four-bit data “000000111111001100011111” by taking account of the all-bit inversion flag of “1”, the number of head “0” bits of “6005”, the number of head “1” bits, the number of tail “0” bits, and the number of tail “1” bits. The circuit 15 produces third twenty-four-bit data “111111000000110011100000” by taking account of the all-bit inversion flag of “0”, the number of heat “0” bits of “0650”, the number of head “1” bits, the number of tail “0” bits, and the number of tail “1” bits. Further, the circuit 15 produces fourth twenty-four-bit data “111111000001100110011111” by taking account of the all-inversion flag of “0”, the number of head “0” bits of “0605”, the number of had “1” bits, the number of tail “0” bits, and the number of tail “1” bits.

The first to fourth twenty-four-bit data have DSVs of “−6”, “+2”, “−2” and “+6”, respectively. Because the last bits of the previous symbol are “ * * * 01111” and because the maximum inversion interval should be “8” or less, only the first and second twenty-four-bit data are qualified. Further, because the head bits of a symbol produced by converting the next data “0010H” are “001 * * * ”, both of the first and second data can be selected. Moreover, because the DSV up to the last bit of the previous symbol is “+8”, a new DSV is “+2” when the first data is selected or “+10” when the second data is selected. Consequently, the first twenty-four-bit data that can reduce the absolute value of the DSV is selected as twenty-four channel bits and output as data Dout.

A second, more specific coding procedure will be described by using specific numerical values hereinafter. Assume that the input data (Din) 20 is “EE16H” (60950), that the last bits of the previous channel bits are “ * * * 01”, that the DSV up to the end of the previous symbol is “+6”, and that the next data bits are “0010H”.

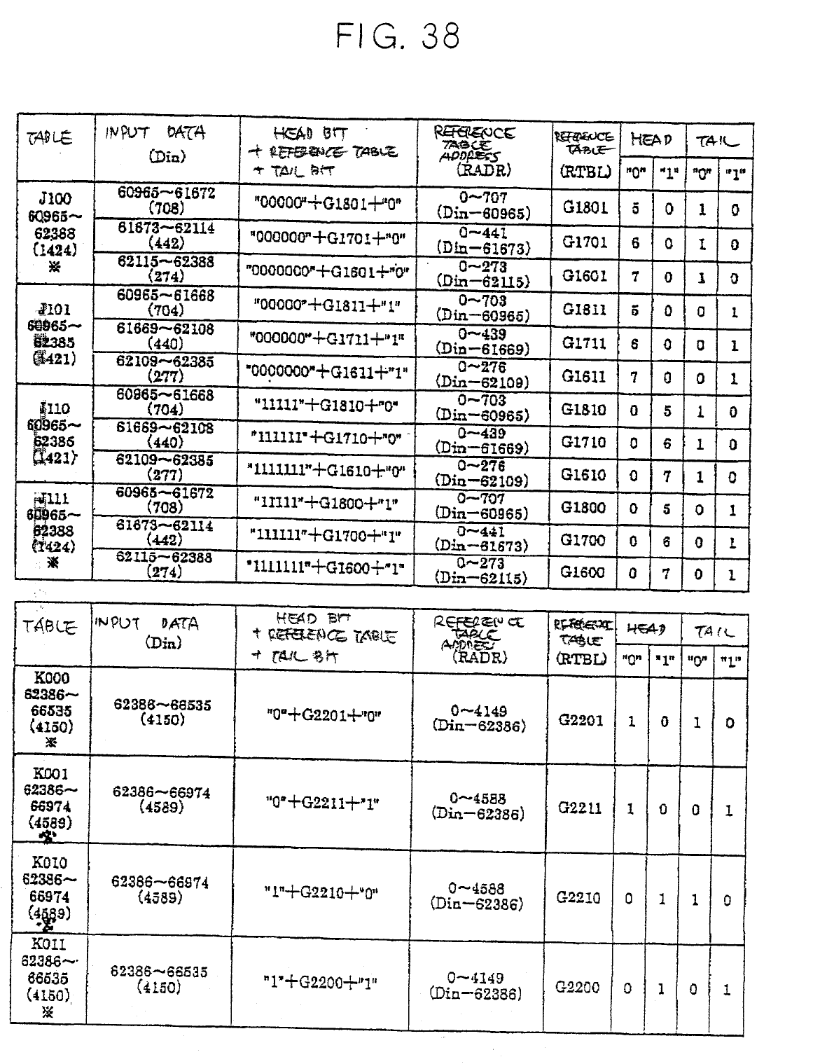

The conversion table processing section 11 selects reference tables. Specifically, the input data (Din) “60950” is contained in, among the conversion tables shown in FIGS. 30 through 37, conversion tables J010 and J011 shown in FIG. 37. In the table J010, “1111”+G1910+“0” and RADR=Din−60047=903 are selected. Further, RTBL=G1910, the number of continuous head “1” bits of “4” and the number of tail “0” bits of “1” are selected. Likewise, in the table J011, “1111”+G1900+“1” and RADR=Din−59842=1108 are selected. Further, RTBL of “G1900”, the number of continues head “1” bits of “4” and the number of tail “1” bits of “1” are selected.

The processing section 11 therefore feeds to the reference table processing section 12 RADRs of 903 and 1108 as reference table addresses 21, ten bits designating the reference tables B1910 and 1900, and two bits representative of “1” that is the number of tables selected. Further, the processing section 11 delivers to the twenty-four channel bits constructing circuit 15 two bits “0” and “0” representative of all-bit inversion flags, twenty-four bits indicative of “0410” and “0401” showing the numbers of head “0” bits, the number of tail “0” bits, and the number of tail “1” bits.

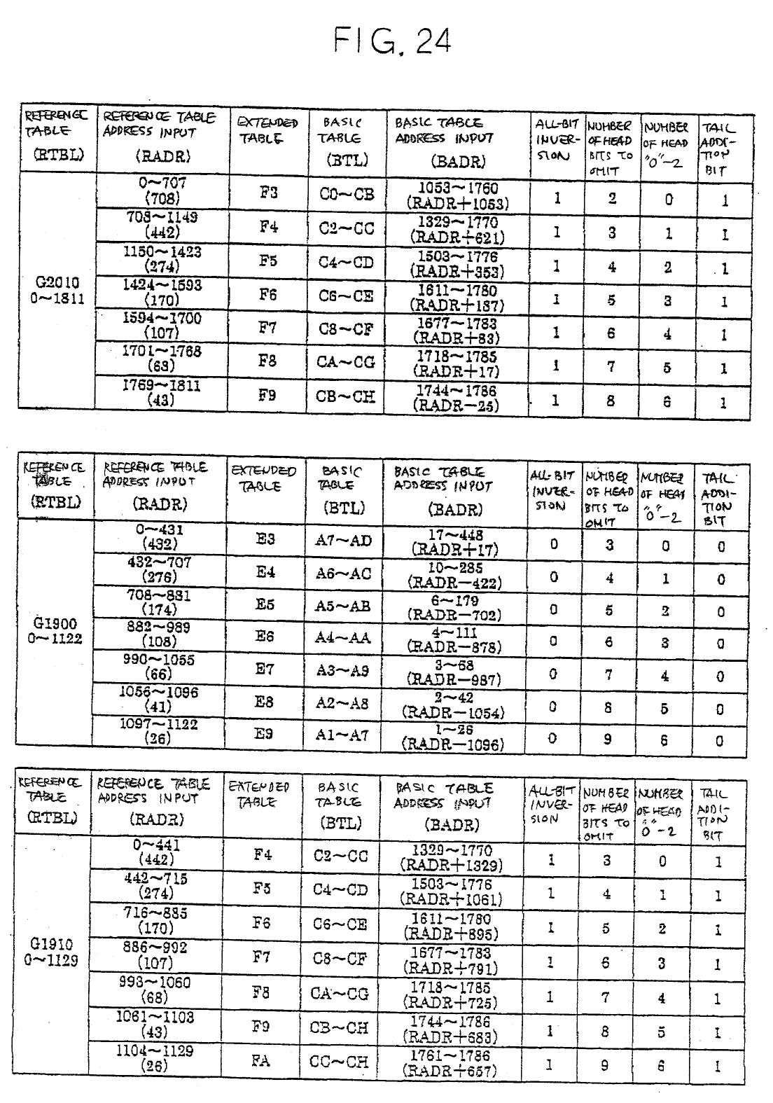

Subsequently, the reference table processing section 12 selects extended tables and basic tables on the basis of the reference tables shown in FIGS. 22 through 30. The reference tables G1910 and G1900 are the reference table information signal 22 corresponding to RADRs of 903 and 1108, respectively, of the two reference table addresses 21, which are received from the conversion table processing 11 as the reference table addresses 21. In RADR=903 in the RTBL G1910, FIG. 24, there are listed an extension table F7, basic tables C8 through CF, BADR=RADR+791=1694, all-bit inversion of “1”, the number of head bits to be omitted of “6”, “number of head “0”−2” of “3”, and the tail addition bit of “1”. Likewise, in RADR=1108 in the RTBL G1900, FIG. 24, there are listed an extension table E9, basic tables A1 through A7, BADR=RADR−1096=12, all-bit inversion of “0”, the number of head bits to be omitted of “9”, “number of head “0”−2” of “6”, and tail addition bit of “0”.

The processing section 12 therefore outputs two basic table addresses (BADRs) of 1694 and 12. The select signal 25 output from the processing section 12 varies to “0” and “1” within a single clock while being fed to the selector 13 and twenty-four channel bits constructing circuit 15. The bit conversion control signal 26 consists of two all-bit inversion bits that are “1” and “0”, ten bits representative of “6” and “9” that are the numbers of head bits to be omitted, six bits that are “3” and “6” representative of “numbers of head “0”−2”, and two bits representative of “1” and “0” that are the numbers of tail bits to be added.

The selector 13 therefore sequentially selects BADRs of 1649 and 12 within a single clock while delivering them to the basic table processing section 14 as the BADR 27.

The basic table processing section 14 searches BADR of 1694 on the table C9 of FIG. 18 in accordance with the basic tables of FIGS. 6 through 21, thereby selecting first seventeen-bit data. Also, the processing section 14 searches for BADR of 12 on the table A6 of FIG. 6, thereby outputting second seventeen-bit data. The first and second seventeen-bit data are “00000011100111100” and “11111111110011000”, respectively. The processing section 14 sequentially feeds the two groups of seventeen-bit data to the twenty-four channel bits constructing circuit 15 as basic table data 28 within a single clock.

The twenty-four channel bits constructing circuit 15 omits all bits of the above first-seventeen bit data, omits six head bits, adds “0000011” to the head, and adds “1” to the tail, thereby outputting first nineteen-bit data “0000011000110000111”. Also, the circuit 15 executes no bit inversion with the second seventeen-bit data “11111111110011000”, omits nine head bits, adds “0000000011” to the had, and adds “0” to the tail, thereby outputting second nineteen-bit data “0000000011100110000”.

Subsequently, the circuit 15 produces first twenty-four-bit data “111100000110001100001110” from the first nineteen-bit data by taking account of the all-bit inversion flag of “0”, the number of head “0” bits that is “0410”, the number of head “1” bits, the number of tail “0” bits, and the number of tail “1” bits. Also, the circuit 15 produces second twenty-four-bit data “111100000000111001100001” from the second nineteen-bit data by taking account of the all-bit inversion flag of “0”, the number of head “0” bits that is “0401”, the number of head “1” bits, the number of tail “0” bits, and the number of tail “1” bits.

The first and second twenty-four-bit data have DSVs of “−2” and “−4”, respectively. Because the tail bits of the previous symbol are “ * * * 01”, the first and second twenty-four-bit data both can be selected. However, because the head bits of a symbol produced by converting the next data “0010H” is “001 * * * ” and because the minimum inversion interval is “2” or less, only the first data can be selected. Consequently, the circuit 15 outputs the first twenty-four-bit data as the output data Dout. In this connection, because the DSV up to the last bit of the previous symbol is “+6”, a new DSV is “+4” when the first data is selected or “+2” when the second data is selected. However, the second data cannot be selected because priority is given to the minimum/maximum inversion interval rule.

Reference will be made to FIG. 3 for describing a specific configuration of the decoding circuitry. The conversion table processing section 31 reversely converts the conversion tables shown in FIGS. 31 through 28. Specifically, the processing section 31 receives input data (Din) 40 having twenty-four channel bits. The processing section 31 counts the number of head “0” bits, the number of head “1” bits, the number of tail “0” bits and the number of tail “1” bits included in the input data 40. The processing section 31 then compares the above numerical values with the conversion tables and selects a table including columns-coinciding with the numerical values. Subsequently, the processing section 31 generates reference data 41 in which the number of subject bits are omitted and a reference table display signal 42 indicative of a reference table to which the reference data belongs. The reference data 41 and reference table indication signal 42 are input to the reference table processing section 32. As a result, the processing section 31 receives a reference table address 45 corresponding to the reference data 41 from the reference table processing section 32. The processing section 31 therefore again uses the conversion table used for the above calculation to thereby form sixteen data bits and output them as output data Dout 46.

The reference table processing section 32 reversely converts the reference tables shown in FIGS. 22 through 30. Specifically, the processing section 32 inputs the reference data 41 and reference table indication signal 42 in the reference table and delivers the calculated seventeen-bit basic table data 43 to the basic table processing section 33. As a result, the processing section 32 receives a reference table address (BADR) 44 from the basic table processing section 33. The processing section 32 again uses the reference table used for data calculation to thereby produce a reference table address (RADR) 45 and feeds it to the conversion table processing section 31.

The basic table processing section 33 deals with the basic tables shown in FIGS. 6 through 21. The processing section 33 received the seventeen-bit basic table data 43 references the basic tables to thereby generate a basic table address (BADR) 44 and feeds it to the reference table processing section 32.

A specific decoding procedure will be described hereinafter. First, the conversion table processing section 31 determines the number of head “0” bits, the number of head “1” bits, the number of tail “0” bits and the number of tail “1” bits included in the input data 40. The processing section 31 then determines a reference table to which the input data 40 belongs. Assume that a reference table number (G number) designating the above reference table has the first bit that is “G”, and the second and third bits that are representative of the numbers of bits of “22” through “10”. These numbers of bits each are a particular number of bits produced by omitting the continuous head or tail “0” bits or the continuous head or tail “1” bits.

Further, assume that the fourth and fifth bits of the reference table number are “00” if the head bit and tail bit after omission both are “0”, or “10” if the head bit and tail bit are “0” and “1”, respectively, or “01” if the head bit and tail bit both are “01”, or “11” if the head bit and tail bit are “1” and “0”, respectively.

Also, assume that the last bit of the reference table number or G number is “1”. Then, the data from which the continuous head “0” or “1” bits and the continuous tail “0” or “1” bits, which are twenty-two bits to ten bits each, have its all bits inverted. At the same time, the last bit of the reference table number is corrected to “0”. For example, in the case of a reference table G2201, twenty-two bit data all are inverted. If the resulting head bit and tail bit both are “0”, then the G number of the reference table is corrected to G2200.

The conversion table processing section 31 omits the continuous head “0” or “1” bits and the continuous tail “0” or “1” bits, which are twenty-two bits to ten bits each, from the reference data 41 and outputs the resulting data. The reference table display signal 42 conveys a five-bit reference table code to the reference table processing section 32.

The reference table processing section 32 finds a basic table by executing reverse calculation with the reference table. Specifically, the processing section 32 omits one tail bit corresponding to the “tail addition bit” of the reference table designated by the reference table display signal 42. The processing circuit 32 then counts the number of head data bits “00 . . . 0011”, subtracts “4” from the number of bits, and uses “number of head “0”−2” equal to the difference as a target data row. More specifically, at the time of coding, a number of “0” indicated by “number of head “0”−2” are arranged and followed by “0011”. Therefore, at the time of decoding, a value produced by subtracting “4” from the number of head bits “00 . . . 0011” of the data bits is equal to “number of head “0”−2”. This calculation, however, cannot determine the row number alone when it comes to the first to seventh rows of the table G2200, the first to third rows and fourth and fifth rows of the table G2210, the first and second rows of the table G2100, and the first and second rows of the table G2110. In this case, up to a basic table address (BADR) can be and is determined, as will be described specifically later.

The processing section 32 determined a reference table row, omits a number of head bits equal to the sum of “00 . . . 0011”, i.e., “number of head “0”−2” and “4” from the data bits. The processing section 32 then adds a number of “1” bits corresponding to the number of head bits omitted. The resulting data are subjected to all-bit inversion and then output as basic table data bits 43 if the all-bit inversion bit is “1” or directly output without inversion if it is “0”. Such processing makes the number of basic table data bits 43 seventeen without exception.

The basic table processing section 33 received the seventeen-bit basic table data bits 43 outputs a thirteen-bit basic table address (BADR) 44 to the reference table processing section 32. This is contrastive to a case wherein a thirteen-bit address (BADR) is transformed to seventeen data bits at the time of coding. It follows that the basic tables (BTLBs) must be configured such that they can be referenced in the reverse direction as well.

The reference table processing section 32 references the reference tables on the basis of the basic table address (BADR) 44 within a single clock, calculates a reference table address (RADR) 45 from the basic table address (BADR) 44, and feeds the address 45 to the conversion table processing section 31.

As for the first to seventh rows and eighth and ninth rows of the table G2200, the first to third rows and fourth and fifth rows of the table G2210, the first and second rows of the table G2100 and the first and second rows of the table G2110, there cannot be finally determined row numbers. However, because a basic table address BADR has already been determined, it is possible to determine a row number on the basis of the data BADRA and therefore to determine a reference table address RADR. For example, in the case of the first to seventh rows of the table G2200 and basic table address BADR of 1650, the sixth row can be searched for on the reference table of FIG. 22. Consequently, by using the equation of BADR=RADR+278, the reference table address (RADR) 45 can be determined to be 1650−278=1372.

The reference table address 45 is again input to he conversion table processing section 31. The processing section 31 references the reference table on the basis of the reference table address 45 within a single clock, calculates one output data Dout designated by the input data Din, and then outputs sixteen-bit output data Dout 46. In this manner, twenty-four channel bits are decoded to sixteen-bit original data.

A first, more specific decoding procedure will be described more by using specific numerals hereinafter. Assume that the conversion table processing section 31 receives the second twenty-four-bit data generated in the first, more specific coding procedure stated earlier, i.e., “000000111111001100011111”. This data has six continuous “0” bits at the head and five continuous “1” bits at the tail. The processing section 31 therefore searches for “6005” in the head bit column and tail bit column of the conversion table. The processing section 31 then searches for “six head “0” bits+G1311+five tail “1” bits” on the table H301, FIG. 35. The table H301 shows that the input data (Din) is “36627-36692”, that the eference table address (RADR) is “0-65” (Din−36627), that a reference table (RTBL) is “G1311”, and that six head “0” bits and five tail “1” bits continuously appear each.

On the reference table G1311, the fourth bit is “1”. The processing section 31 therefore executes all-bit inversion and correction to a table number G1310. The processing section 31 then outputs thirteen-bit data “0000001100111” and table number G1310 as reference data 41 and reference table display signal 42, respectively.

Subsequently, the reference table processing section 32 omits one bit, which is the tail addition bit, from the reference table G1310, FIG. 28, to thereby produce twelve-bit data “000000110011”. Because the twelve-bit data has eight bits “00000011” at its head, the processing section 32 subtracts “4” from “8” and then selects the fifth row in which “number of head “0”−2” is “4”. As a result, there are determined a reference table address (RADR) 59-62, an extended table FE, basic tables CG-CI, a basic table address 1784-1787 (RADR+1725), all-bit inversion of “1”, the number of head bits omitted that is 13, “number of head “0”−2” of “4”, and tail addition bit of “1”.

Because “number of head “0”−2” is “4”, the processing section 32 omits the head data “00000011” of the twelve-bit data. Subsequently, the processing section 32 adds thirteen bits of “1” to the head because the number of head bits omitted is “13”, thereby outputting seventeen-bit data “11111111111110011”. The processing section 32 then inverts all bits because the all-bit inversion bit is “1” to thereby output “00000000000001100”. This seventeen-bit data is input tot he basic table processing section 33 a basic table data bits 43.

Subsequently, the basic table processing section 33 finds the table CG, FIG. 18, and address 1785 on the basis of the seventeen-bit basic table data 43. The processing section 33 then feeds “1785” to the reference table processing section 32 as a basic table address (BADR) 44.

The reference table processing section 32 calculates Din=60+36627=36687 by using RADR (Din−36627=60) on the fourth row of the conversion table H301. The processing section 32 then outputs 8F4FH (36687) as data bits. This value is equal to the value of the input data dealt with in the first, more specific coding procedure.

A second, more specific decoding procedure will be described by using specific numerical values hereinafter. Assume that the second twenty-four-bit data “111100000000111001100001” generated in the second, more specific coding procedure stated earlier is the input data (Din) 40. Then, the conversion table processing section 31 sees that the input data 40 has four continuous “1” bits at the head and has a single “1” bit at the tail. The processing section 31 therefore searches for “0201” on the conversion tables and finds it on the table J011, FIG. 37. The processing section 31 then searches for “four head “1” bits+G1900+one tail “1” bit” on the table J011. The table J011 shows that the input data (Din) is 59842-60964, that RADR is 0-1122 (Din−59842), that RTBL is G1900, and that four head “1” bits and one tail “1” bit exist.

Because the fourth bit of the reference table G1900 is “0”, the processing section 31 corrects the input data (Din) except for the above five bits to thereby output nineteen-bit data “0000000011100110000” as reference data 41. At the same time, the processing section 31 outputs five bits representative of the table G1900 as a reference indication display signal.

Subsequently, by referencing the reference table G1900, FIG. 24, the processing section 32 omits one bit corresponding to a tail addition bit from the nineteen-bit data to thereby produce eighteen-bit data “000000001110011000”. Because the head portion “0000000011” of this data has ten bits, the processing section 32 calculates 10−4=6 and then selects the seventh row on which “number of head “0”−2” is “6”. Consequently, the processing section 32 finds RADR of 1097-1122, an extended table E9, basic tables A1-A7, BADR of 1-26 (RADR−1096), all-bit inversion of “1”, omission of nine head bits, “number of head “0”−2” of “6”, and addition of no tail bits.

Because “number of head “0”−2” is “6”, the processing section 32 omits the head portion “0000000011” of the eighteen-bit data to thereby produce “10011000”. Further, because the number of head bits omitted is “9”, the processing section 32 adds 9 “1” bits to the head of the above data to thereby output seventeen-bit data “11111111110011000”. Because all-bit inversion is “0”, the processing section 32 feeds the seventeen-bit data to the basic table processing section 33 as basic table data bits 43.

The basic table processing section 33 finds a table CA6, FIG. 6, and an address 12 in accordance with the seventeen-bit data “11111111110011000”. The processing section 33 feeds “12” to the reference table processing section 32 as a basic table address (BADR) 44.

The reference table processing section 32 obtains a reference table address (RADR) of “1108” from the seventh row of the reference table G1900 selected previously, i.e., RADR−1096=12. The processing section 32 feeds the reference table address “1108” to the conversion table processing section 31 as a reference table address 45.

The conversion table processing section 31 obtains Din=1108+59842=60950 from the third row of the conversion table J011, i.e., RADR of Din−59842=1108. The processing section 31 then outputs EE16H (60950) as sixteen data bits. This value is equal to the value of the input data described in relation to the second, more specific 16-to-24 coding procedure.

In the basic tables shown in FIGS. 6 through 21, 2220 addresses far smaller in number than 65536 codes, which are produced by arranging sixteen bits, are arranged in seventeen bits under preselected conditions. Alternatively, the addresses may be arranged in eighteen bits, in which case data bit identical with the seventeenth bit will be positioned at the eighteenth bit. This makes “tail addition bit” shown in FIGS. 22 through 30 and therefore processing associated therewith needless.

In the basic tables shown in FIGS. 6 through 21, the first bit to the sixteenth bit, i.e., sixteen bits in total may be directly used in place of seventeen bits. In such a case, for the first bit to the sixteenth bit, use is made of the basic tables of FIGS. 6 through 21. For the seventeenth bit, “0” is used when BADR is “0-1787” while “1” is used when BADR is “1788-2219”. Therefore, in the event of coding, data is determined on the basis of the address range, as stated earlier. In the event of decoding, BADR is determined to be “0-1787” when the seventeenth bit is “0” or “1788-2219” when it is “1”.

The illustrative embodiment has been shown and described as coding sixteen-bit data to twenty-four-bit data and decoding the latter to the former. However, the crux of the present invention is that m-bit data is coded to n-bit data greater than m while the latter is decoded to the former. In this case, use is made of basic tables on which m-bit data are arranged by a number smaller than 2^{m} and extended tables derived from the basic tables.

In the illustrative embodiment, a plurality of table processing sections each controls respective tables. If desired, the plurality of table processing sections may be replaced with a single converting means capable of executing the sequence of processing by using the tables.

In summary, it will be seen that the present invention provides a code converter capable of converting codes with a minimum number of tables and therefore with a minimum of circuit scale.

Various modifications will become possible for those skilled in the art after receiving the teachings of the present disclosure without departing from the scope thereof.

What is claimed is:

1. A code converter for converting m data bits to n channel bits (m<n) and recording said n channel bits, said code converter comprising:
a basic table comprising a plurality of tables smaller in number than 2^{m} defined on the basis of a bit pattern required of the codes; and
a converting means for coding all data of the m data bits to the n channel bits by calculation using said basic table.

2. The code converter as claimed in claim 1, wherein when converting the n channel bits coded to the m channel bits to thereby reproduce data, said converting means performs reverse calculation with said basic table to thereby decode all data of said n channel bits to said m data bits.

3. The code converter as claimed in claim 2, wherein m and n are “16” and “24”, respectively.

4. The code converter as claimed in claim 3, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.

5. The code converter as claimed in claim 1, wherein said tables constituting said basic table lists at least one of address inputs having a number of bits less than m and data outputs having a number of bits smaller than n.

6. The code converter as claimed in claim 5, wherein when converting the n channel bits coded to the m channel bits to thereby reproduce data, said converting means performs reverse calculation with said basic table to thereby decode all data of said n channel bits to said m data bits.

7. The code converter as claimed in claim 6, wherein m and n are “16” and “24”, respectively.

8. The code converter as claimed in claim 7, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.

9. The code converter as claimed in claim 5, wherein m and n are “16” and “24”, respectively.

10. The code converter as claimed in claim 9, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.

11. The code converter as claimed in claim 1, further comprising:
a plurality of reference table listing, as data outputs, basic table addresses assigned to said basic table; and
a conversion table listing, as data outputs, reference table addresses that designated said reference table on the basis of input data.

12. The code converter as claimed in claim 11, wherein said conversion table comprises a plurality of conversion table group, each of which includes at least one conversion table and lists the address of the reference table corresponding to said conversion table and control bits, and
said reference tables each list an address of said basic table corresponding thereto and control bits.

13. The code converter as claimed in claim 12, wherein assuming a total number j of particular ranges implemented as said conversion table groups corresponding to 2^{m} patterns, said conversion table comprises i (1≦i) tables in a range number Lk (1≦k≦j).

14. The code converter as claimed in claim 13, wherein m and n are “16” and “24”, respectively.

15. The code converter as claimed in claim 14, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.

16. The code converter as claimed in claim 13, wherein assuming that j is “16” and that k lies in a range of 1≦k≦16, then i is “1” for range numbers L1, L2, L3 and L4, “2” for range numbers L5, L6, L7, L8, L10, L11, L13 and L14, or “4” for range numbers L9, L12, L15 and L16.

17. The code converter as claimed in claim 11, wherein said converting means selects, based on input data, a reference table group out of at least one reference table assigned to a range to which said input data belongs, determines a reference table, a reference table address and control bits, determines basic data bits on the basis of a basic table, determines at least one n-bit candidate data on the basis of said basic data bits, said control bits of said conversion table and said control bits of said reference table, and selects, if a plurality of candidate data exist, optimal one of said plurality of candidate data.

18. The code converter as claimed in claim 17, wherein to determine the optimal candidate data, said converting means minimizes an absolute value of a DSV (Digital Sum Variation) within a range satisfying a minimum inversion interval rule, a maximum inversion interval rule, and a minimum inversion interval continuation rule.

19. The code converter as claimed in claim 18, wherein m and n are “16” and “24”, respectively.

20. The code converter as claimed in claim 19, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.

21. The code converter as claimed in claim 17, wherein when converting the n channel bits coded to the m data bits to thereby reproduce data, said converting means selects a conversion table on the basis of a head bit and a tail bit of input channel bit data, executes inversion/non-inversion of bits on the basis of a reference table address listed on said conversion table, determines a reference table on the basis of said conversion table and a head bit of resulting data, executes bit omission, bit addition and inversion/non-inversion, determines a basic table address on the basis of resulting data, determines a reference table address by again using said reference table as said basic table address, and again selects a conversion table address out of said conversion table on the basis of said reference table address to thereby output said m data bits.

22. The code converter as claimed in claim 21, wherein m and n are “16” and “24”, respectively.

23. The code converter as claimed in claim 22, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.

24. The code converter as claimed in claim 17, wherein m and n are “16” and “24”, respectively.

25. The code converter as claimed in claim 24, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.

26. The code converter as claimed in claim 12, wherein m and n are “16” and “24”, respectively.

27. The code converter as claimed in claim 26, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.

28. The code converter as claimed in claim 11, wherein m and n are “16” and “24”, respectively.

29. The code converter as claimed in claim 28, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.

30. The code converter as claimed in claim 1, wherein m and n are “16” and “24”, respectively.

31. The code converter as claimed in claim 30, wherein said basic table lists 2220 seventeen-bit patterns each being any one of a pattern not including inversion between two nearby bits except for a head portion and a tail portion, a pattern whose two head bits are “00”, “10” or “11”, a pattern in which a maximum number of identical continuous bits except for a head portion and a tail portion is eight, a pattern in which a maximum number of identical continuous bits is seven in a tail portion, a pattern including, when two head bits of said pattern are “11 or “10”, five times of inversion of “0” and “1” or less, a pattern including, when two head bits of said pattern are “00”, six times of inversion of “0” and “1” or less, and a pattern whose seventeen bits all are “0”.
